(19) United States
(12) Patent Application Publication
(10) Pub. No.: US 2022/0327364 A1
(43) Pub. Date: Oct. 13, 2022

(54) SEMICONDUCTOR DEVICE GEOMETRY METHOD AND SYSTEM

(71) Applicant: ASML NETHERLANDS B.V., Veldhoven (NL)

(72) Inventors: Stefan HUNSCHE, Santa Clara, CA (US); Fuming WANG, Santa Clara, CA (US); Ya LUO, Saratoga, CA (US); Pioter NIKOLSKI, Veldhoven (NL)

(73) Assignee: ASML NETHERLANDS B.V., Veldhoven (NL)

(21) Appl. No.: 17/638,472

(22) PCT Filed: Jul. 31, 2020
(86) PCT No.: PCT/EP2020/071741

§ 371 Date: Feb. 25, 2022

Related U.S. Application Data
(60) Provisional application No. 62/894,474, filed on Aug. 30, 2019.
(60) Provisional application No. 62/980,520, filed on Feb. 24, 2020.
(60) Provisional application No. 63/042,654, filed on Jun. 23, 2020.

(51) Int. Cl. G06N 3/06; G06N 7/00; G06T 7/00

(52) U.S. Cl. CPC G06N 3/06; G06N 7/005; G06T 7/0006

(57) ABSTRACT

Systems and methods for predicting substrate geometry associated with a patterning process are described. Input information including geometry information and/or process information for a pattern is received and, using a machine learning prediction model, multi-dimensional output substrate geometry is predicted. The multi-dimensional output information may include pattern probability images. A stochastic edge placement error band and/or a stochastic failure rate may be predicted. The input information can include simulated aerial images, simulated resist images, target substrate dimensions, and/or data from a lithography apparatus associated with device manufacturing. Different aerial images may correspond to different heights in resist layers associated with the patterning process, for example.

### CROSS-REFERENCE TO RELATED APPLICATIONS

This application claims priority of U.S. application 62/894,474 which was filed on Aug. 30, 2019 and U.S. application 62/980,520 which was filed on Feb. 24, 2020 and U.S. application 63/042,654 which was filed on Jun. 23, 2020 which are incorporated herein in its entirety by reference.

### TECHNICAL FIELD

The description herein relates generally to lithography in semiconductor manufacturing methods and systems.

### BACKGROUND

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc.

Manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced. At the same time, the number of functional elements, such as transistors, per device has been steadily increasing, following a trend commonly referred to as “Moore”s law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k1 lithography, according to the resolution formula CD=k1×λ/NA, where λ is the wavelength of radiation employed (currently in most cases 248 nm or 193 nm), NA is the numerical aperture of projection optics in the lithographic projection apparatus, CD is the “critical dimension”-generally the smallest feature size printed-and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

OPC and other RET utilize robust electronic models that describe the lithography process. Calibration procedures for such lithography models are thus desired that provide valid, robust, and accurate models across the process window. Currently, calibration is done using a certain number of 1-dimensional and/or 2-dimensional gauge patterns with wafer measurements. More specifically, the 1-dimensional gauge patterns include line-space patterns with a varying pitch and critical dimension (CD), isolated lines, multiple lines, etc. The 2-dimensional gauge patterns typically include line-ends, contacts, and randomly selected SRAM (Static Random Access Memory) patterns.

### SUMMARY

According to an embodiment, there is provided one or more non-transitory, computer readable media storing a machine learning prediction model and instructions that, when executed by one or more processors, cause the one or more processors to: receive input information including geometry information and/or process information for a pattern; and predict, using the machine learning prediction model, multi-dimensional output substrate geometry based on the input information. The predicting comprises determining an edge placement error (EPE) metric associated with one or more features of the pattern based on the input information and/or the output substrate geometry.

In an embodiment, the EPE metric is symmetric or asymmetric for the one or more features of the pattern.

In an embodiment, an asymmetric EPE metric has a non-Gaussian distribution.

In an embodiment, the machine learning prediction model is trained using asymmetrically distributed training data such that weights and/or parameters of the trained machine learning prediction model facilitate determination of the symmetric or asymmetric EPE metric.

In an embodiment, the asymmetrically distributed training data comprises asymmetrically distributed EPE metrics determined from multi-dimensional probability images associated with asymmetrically distributed critical dimension (CD) values.

In an embodiment, the multi-dimensional output substrate geometry indicates variability in shapes of features of the pattern.

In an embodiment, the multi-dimensional output substrate geometry indicates a probability that given geometry occupies a given location on a substrate.

In an embodiment, the multi-dimensional output substrate geometry comprises a representation of pattern probability in a plurality of dimensions.

In an embodiment, the representation of pattern probability comprises a pattern probability image that comprises predicted probabilities of two-dimensional substrate geometry for the one or more features of the pattern.

In an embodiment, the pattern probability image comprises a plurality of stacked images comprising predicted probabilities of two-dimensional substrate geometry for one or more vias.

In an embodiment, the instructions are further configured to cause the one or more processors to predict, with the machine learning prediction model, one or both of (1) a symmetric or asymmetric stochastic edge placement error band and (2) a stochastic failure rate, based on the multi-dimensional output substrate geometry.

In an embodiment, the instructions are further configured to cause the one or more processors to tune the machine learning prediction model such that the multi-dimensional output substrate geometry matches a measured stochastic edge placement error band or measured failure rate.

In an embodiment, the instructions are further configured to cause the one or more processors to tune the machine learning prediction model such that the multi-dimensional output substrate geometry corresponds to, or matches, a mean contour prediction from an optical proximity correction model or a lithography manufacturability check model.

In an embodiment, the multi-dimensional output substrate geometry is associated with a pattern in a substrate in a semiconductor device and a patterning process comprises a semiconductor device manufacturing process.

In an embodiment, the multi-dimensional output substrate geometry comprises a pattern probability image, and wherein the pattern probability image comprises predicted two-dimensional geometry of one or more vias in a semiconductor device.

In an embodiment, the multi-dimensional output substrate geometry comprises a pattern probability image, and wherein the instructions are further configured to cause the one or more processors to use the pattern probability image for a lithography manufacturability check and/or pattern fidelity metrology in a semiconductor device manufacturing process.

In an embodiment, the input information comprises one or more of a simulated aerial image, a simulated resist image, target substrate dimensions, or data from a scanner associated with semiconductor device manufacturing, for a semiconductor device.

In an embodiment, the input information comprises a plurality of aerial images, and individual aerial images of the plurality of aerial images correspond to different heights in resist layers associated with a patterning process.

In an embodiment, the machine learning prediction model comprises a neural network.

In an embodiment, the process information comprises one or more parameters for one or more manufacturing processes performed for a semiconductor device.

In an embodiment, the instructions are further configured to cause the one or more processors to train the machine learning prediction model with training information comprising one or more of aerial images, target pattern geometry, or patterning process parameters, and corresponding physical substrate measurements and/or predictions from a different non-machine learning prediction model.

In an embodiment, the corresponding physical substrate measurements and/or predictions from a different non-machine learning prediction model comprise training pattern probability images.

In an embodiment, the instructions are further configured to cause the one or more processors to determine an adjustment for a semiconductor device manufacturing apparatus based on the predicted multi-dimensional output substrate geometry.

In an embodiment, the instructions are further configured to cause the one or more processors to calibrate the machine learning prediction model based on one or both of after development inspection dimensions and after etch inspection dimensions associated with a semiconductor device manufacturing process.

According to another embodiment, there is provided a method for predicting substrate geometry associated with a patterning process, the method comprising: receiving input information including geometry information and/or process information for a pattern; and predicting, using a machine learning prediction model, multi-dimensional output substrate geometry based on the input information. The predicting comprises determining an edge placement error (EPE) metric associated with one or more features of the pattern based on the input information and/or the output substrate geometry.

In an embodiment, the EPE metric is symmetric or asymmetric for the one or more features of the pattern.

In an embodiment, an asymmetric EPE metric has a non-Gaussian distribution.

In an embodiment, the machine learning prediction model is trained using asymmetrically distributed training data such that weights and/or parameters of the trained machine learning prediction model facilitate prediction of the symmetric or asymmetric EPE metric.

In an embodiment, the asymmetrically distributed training data comprises asymmetrically distributed EPE metrics determined from multi-dimensional probability images associated with asymmetrically distributed critical dimension (CD) values.

In an embodiment, the multi-dimensional output substrate geometry indicates variability in shapes of features of the pattern.

In an embodiment, the multi-dimensional output substrate geometry indicates a probability that given geometry occupies a given location on a substrate.

In an embodiment, the multi-dimensional output substrate geometry comprises a representation of pattern probability in a plurality of dimensions.

In an embodiment, the representation of pattern probability comprises a pattern probability image that comprises predicted probabilities of two-dimensional substrate geometry for the one or more features of the pattern.

In an embodiment, the pattern probability image comprises a plurality of stacked images comprising predicted probabilities of two-dimensional substrate geometry for one or more vias.

In an embodiment, the method further comprises predicting, with the machine learning prediction model, one or both of (1) a symmetric or asymmetric stochastic edge placement error band and (2) a stochastic failure rate, based on the multi-dimensional output substrate geometry.

In an embodiment, the method further comprises tuning the machine learning prediction model such that the multi-dimensional output substrate geometry matches a measured stochastic edge placement error band or measured failure rate.

In an embodiment, the method further comprises tuning the machine learning prediction model such that the multi-dimensional output substrate geometry corresponds to, or matches, a mean contour prediction from an optical proximity correction model or a lithography manufacturability check model.

In an embodiment, the multi-dimensional output substrate geometry is associated with a pattern in a substrate in a semiconductor device and the patterning process comprises a semiconductor device manufacturing process.

In an embodiment, the multi-dimensional output substrate geometry comprises a pattern probability image, and wherein the pattern probability image comprises predicted two-dimensional geometry of one or more vias in a semiconductor device.

In an embodiment, the multi-dimensional output substrate geometry comprises a pattern probability image, and wherein the method further comprises using the pattern probability image for a lithography manufacturability check and/or pattern fidelity metrology in a semiconductor device manufacturing process.

In an embodiment, the input information comprises one or more of a simulated aerial image, a simulated resist image, target substrate dimensions, or data from a scanner associated with semiconductor device manufacturing, for a semiconductor device.

In an embodiment, the input information comprises a plurality of aerial images, and individual aerial images of the plurality of aerial images correspond to different heights in resist layers associated with the patterning process.

In an embodiment, the machine learning prediction model comprises a neural network.

In an embodiment, the process information comprises one or more parameters for one or more manufacturing processes performed for a semiconductor device.

In an embodiment, the method further comprises training the machine learning prediction model with training information comprising one or more of aerial images, target pattern geometry, or patterning process parameters, and corresponding physical substrate measurements and/or predictions from a different non-machine learning prediction model.

In an embodiment, the corresponding physical substrate measurements and/or predictions from a different non-machine learning prediction model comprising training pattern probability images.

In an embodiment, the method further comprises determining an adjustment for a semiconductor device manufacturing apparatus based on the predicted multi-dimensional output substrate geometry.

In an embodiment, the method further comprises calibrating the machine learning prediction model based on one or both of after development inspection dimensions and after etch inspection dimensions associated with a semiconductor device manufacturing process.

According to an embodiment, there is provided a method comprising: receiving, with one or more processors, input information including geometry information and/or patterning process information for a pattern on a substrate; determining, with the one or more processors, an edge placement error (EPE) metric associated with one or more features of the pattern based on the input information; and determining, with the one or more processors, one or more areas of the pattern on the substrate that have one or more potential defects based on the EPE metric.

In an embodiment, the EPE metric is symmetric or asymmetric for the one or more features of the pattern.

In an embodiment, an asymmetric EPE metric has a non-Gaussian distribution.

In an embodiment, the EPE metric is determined with a machine learning prediction model, and the machine learning prediction model is trained using asymmetrically distributed training data such that weights and/or parameters of the trained machine learning prediction model facilitate prediction of the EPE metric whether the EPE metric is symmetric or asymmetric.

In an embodiment, the asymmetrically distributed training data comprises asymmetrically distributed EPE metrics determined from multi-dimensional probability images associated with asymmetrically distributed critical dimension (CD) values.

In an embodiment, the one or more areas of the pattern on the substrate that have the one or more potential defects comprise hot spots.

In an embodiment, the EPE metric is correlated to a yield associated with the pattern on the substrate.

In an embodiment, the input information comprises one or more parameters related to global overlay, a global critical dimension, local overlay, a local critical dimension, a line edge roughness, a local placement error, or a local critical dimension uniformity; and/or a value indicative of an interaction between two or more of the parameters.

In an embodiment, the input information is measured and/or simulated.

According to another embodiment, there is provided a manufacturing process, the process comprising: receiving, with one or more processors, input information including geometry information and/or patterning process information for a pattern on a substrate; determining, with the one or more processors, an edge placement error (EPE) metric associated with one or more features of the pattern based on the input information; and determining, with the one or more processors, one or more areas of the pattern on the substrate that have one or more potential defects based on the EPE metric.

In an embodiment, the EPE metric is symmetric or asymmetric across the one or more features of the pattern.

In an embodiment, an asymmetric EPE metric has a non-Gaussian distribution.

In an embodiment, the EPE metric is determined with a machine learning prediction model, and the machine learning prediction model is trained using asymmetrically distributed training data such that weights and/or parameters of the trained machine learning prediction model facilitate prediction of the EPE metric whether the EPE metric is symmetric or asymmetric.

In an embodiment, the asymmetrically distributed training data comprises asymmetrically distributed EPE metrics determined from multi-dimensional probability images associated with asymmetrically distributed critical dimension (CD) values.

In an embodiment, the one or more areas of the pattern on the substrate that have the one or more potential defects comprise hot spots.

In an embodiment, the EPE metric is correlated to a yield associated with the pattern on the substrate.

In an embodiment, the input information comprises one or more parameters including global overlay, a global critical dimension, a local critical dimension, a feature edge roughness, a local critical dimension uniformity, mask critical dimension, mask placement error, scanner to scanner critical dimension, scanner to scanner overlay mismatches, patterning tool critical dimension, patterning tool overlay mismatches, or local and global variations of feature asymmetry; and/or a value indicative of an interaction/cross-talk between two or more of the parameters.

In an embodiment, the EPE metric comprises a combination of two or more of the parameters and/or the value indicative of the interaction between two or more of the parameters.

In an embodiment, the EPE metric is mathematically calculated and/or predicted based on one or more of the parameters and/or the value indicative of the interaction between two or more of the parameters.

In an embodiment, the input information is measured and/or simulated.

In an embodiment, the EPE metric is determined based on a target EPE probability level, the one or more processors configured such that the target EPE probability level is entered or selected by a user via a user interface.

In an embodiment, receiving the input information, determining the EPE metric, and determining the one or more areas of the pattern on the substrate that have one or more potential defects are performed as part of an assessment, improvement, prediction, or verification of semiconductor device performance, wherein the assessment, improvement, prediction, or verification of semiconductor device performance comprises source mask optimization, optical proximity correction, a lithography manufacturability check, and/or a design for manufacturing flow associated with a semiconductor device.

In an embodiment, determining one or more areas of the pattern on the substrate that have one or more potential defects based on the EPE metric comprises determining a probability that a given feature of the pattern occupies a given location on the substrate.

In an embodiment, determining one or more areas of the pattern on the substrate that have one or more potential defects based on the EPE metric is based on a cost function that balances an acceptable defect probability with resources required to inspect the number of the one or more areas, wherein the acceptable defect probability is related to a number of the one or more areas of the pattern on the substrate that have the one or more potential defects that are targeted for inspection.

In an embodiment, determining the one or more areas of the pattern on the substrate that have the one or more potential defects based on the EPE metric comprises determining a pattern probability image for one or more features of the pattern.

In an embodiment, the pattern probability image comprises predicted two-dimensional substrate geometry for one or more of the features.

In an embodiment, the input information comprises and/or is determined based on one or more of a predicted aerial image, target substrate dimensions, or data from a scanner and/or patterning process associated with semiconductor device manufacturing, for one or more layers of a semiconductor device.

In an embodiment, the process further comprises determining an adjustment for a semiconductor device manufacturing apparatus based on the one or more areas of the pattern on the substrate that have the one or more potential defects.

In an embodiment, the adjustment comprises one or more of a change in the pattern, a change in a mask, a change of a dose, a change in a focus, a change in an exposure, a change in a pupil, a change in an etch and/or deposition process temperature, or a change in an etch and/or deposition process time.

In an embodiment, the one or more processors comprise a computational lithography model, and wherein determining the EPE metric comprises predicting the EPE metric using the input information as input to the computational lithography model.

In an embodiment, the geometry information comprises one or more indications of a size and/or a position of one or more features of the pattern.

According to an embodiment, there is provided a non-transitory computer readable medium having instructions thereon, the instructions when executed by a computer implementing the process of any of the embodiments described above.

According to an embodiment, there is provided a non-transitory computer readable medium having instructions thereon, the instructions when executed by a computer causing the computer to: receive input information including geometry information and/or patterning process information for a pattern on a substrate; determine an edge placement error (EPE) metric associated with one or more features of the pattern based on the input information; and identify one or more areas of the pattern on the substrate that have one or more potential defects based on the EPE metric.

In an embodiment, the EPE metric is symmetric or asymmetric across the one or more features of the pattern.

In an embodiment, an asymmetric EPE metric has a non-Gaussian distribution.

In an embodiment, the EPE metric is determined with a machine learning prediction model, and wherein the machine learning prediction model is trained using asymmetrically distributed training data such that weights and/or parameters of the trained machine learning prediction model facilitate prediction of the EPE metric whether the EPE metric is symmetric or asymmetric.

In an embodiment, the asymmetrically distributed training data comprises asymmetrically distributed EPE metrics determined from multi-dimensional probability images associated with asymmetrically distributed critical dimension (CD) values.

In an embodiment, the one or more areas of the pattern on the substrate that have the one or more potential defects comprise hot spots.

In an embodiment, the EPE metric is correlated to a yield associated with the pattern on the substrate.

In an embodiment, the input information comprises one or more parameters including global overlay, a global critical dimension, a local critical dimension, a feature edge roughness, a local critical dimension uniformity, mask critical dimension, mask placement error, scanner to scanner critical dimension, scanner to scanner overlay mismatches, patterning tool critical dimension, patterning tool overlay mismatches, or local and global variations of feature asymmetry; and/or a value indicative of an interaction/cross-talk between two or more of the parameters.

In an embodiment, the EPE metric comprises a combination of two or more of the parameters and/or the value indicative of the interaction between two or more of the parameters.

In an embodiment, the input information is measured and/or simulated.

In an embodiment, the EPE metric is determined based on a target EPE probability level, wherein the target EPE probability level is entered or selected by a user via a user interface.

In an embodiment, receiving the input information, determining the EPE metric, and determining the one or more areas of the pattern on the substrate that have one or more potential defects are performed as part of source mask optimization, optical proximity correction, a lithography manufacturability check, and/or a design for manufacturing flow associated with a semiconductor device.

In an embodiment, determining one or more areas of the pattern on the substrate that have one or more potential defects based on the EPE metric comprises determining a probability that a given feature occupies a given location on the substrate.

In an embodiment, determining one or more areas of the pattern on the substrate that have one or more potential defects based on the EPE metric is based on a cost function that balances a number of the one or more areas of the pattern on the substrate that have one or more potential defects versus resources required to inspect the number of the one or more areas.

In an embodiment, determining the one or more areas of the pattern on the substrate that have the one or more potential defects based on the EPE metric comprises determining a pattern probability image for one or more features of the pattern.

According to an embodiment, there are provided one or more non-transitory, computer readable media storing a machine learning prediction model and instructions that, when executed by one or more processors, cause the one or more processors to: receive input information including geometry information and/or patterning process information for a semiconductor device manufacturing process; predict, using the machine learning prediction model, output semiconductor device geometry based on the input information, the output semiconductor device geometry comprising a representation of pattern probability in a plurality of dimensions, the predicting comprising determining an edge placement error (EPE) metric associated with one or more features of a pattern based on the input information and/or the output semiconductor device geometry; receive new input information determined based on an adjustment to the semiconductor device manufacturing process, the adjustment determined based on the output semiconductor device geometry; and predict, using the machine learning model, updated output semiconductor device geometry (i) based on the new input information, (ii) including determining an updated EPE metric based on the new input information and/or the updated output semiconductor device geometry.

In an embodiment, the representation of pattern probability comprises a pattern probability image that comprises predicted two-dimensional substrate geometry for one or more features of the pattern.

In an embodiment, the representation of pattern probability comprises predicted two-dimensional geometry of one or more vias in a semiconductor device.

In an embodiment, the instructions are further configured to cause the one or more processors to predict, with the machine learning prediction model, one or both of (1) a symmetric or asymmetric stochastic edge placement error band and (2) a stochastic failure rate, based on the pattern probability image.

In an embodiment, the input information comprises one or both of a simulated aerial image and a simulated resist image.

### BRIEF DESCRIPTION OF THE DRAWINGS

The accompanying drawings, which are incorporated in and constitute a part of the specification, illustrate one or more embodiments and, together with the description, explain these embodiments. Embodiments of the invention will now be described, by way of example only, with reference to the accompanying schematic drawings in which corresponding reference symbols indicate corresponding parts, and in which:

FIG. 1 illustrates a block diagram of various subsystems of a lithographic projection apparatus, according to an embodiment.

FIG. 2 illustrates an exemplary flow chart for simulating lithography in a lithographic projection apparatus, according to an embodiment.

FIG. 3 illustrates a present method, according to an embodiment.

FIG. 4 illustrates receiving input information, predicting multi-dimensional output substrate geometry using a machine learning prediction model, and performing process monitoring operations, according to an embodiment.

FIG. 5 illustrates a predicted pattern probability image, according to an embodiment.

FIG. 6 illustrates making multi-dimensional output substrate geometry probability predictions based on a non-linear scale, according to an embodiment.

FIG. 7 illustrates pattern probability images predicted by the machine learning prediction model for various dose and focus conditions, according to an embodiment.

FIG. 8 illustrates edge placement error (EPE), according to an embodiment.

FIG. 9 illustrates another present method, according to an embodiment.

FIG. 10 illustrates EPE contributors used to determine an EPE metric, according to an embodiment.

FIG. 11 illustrates a pattern probability image, according to an embodiment.

FIG. 12 illustrates symmetric and asymmetric predicted edge placement error (EPE), according to an embodiment.

FIG. 13 is a block diagram of an example computer system, according to an embodiment.

FIG. 14 is a schematic diagram of a lithographic projection apparatus, according to an embodiment.

FIG. 15 is a schematic diagram of another lithographic projection apparatus, according to an embodiment.

FIG. 16 is a detailed view of a lithographic projection apparatus, according to an embodiment.

FIG. 17 is a detailed view of the source collector module of the lithographic projection apparatus, according to an embodiment.

FIG. 18 schematically depicts an embodiment of an electron beam inspection apparatus, according to an embodiment.

FIG. 19 schematically illustrates another embodiment of an inspection apparatus, according to an embodiment.

### DETAILED DESCRIPTION

With the introduction of extreme ultra violet (EUV) lithography, stochastic variability effects are becoming a dominant source of patterning errors such as edge placement errors and catastrophic pattern failures. It would be helpful to characterize the resulting effects of stochastic edge placement errors, local CD variations (e.g., local CD uniformity—LCDU), missing pattern features, bridging pattern features, and/or other features of a pattern in detail, such as in a statistical (e.g., probabilistic) sense. Effort has been made to identify simple, but suitable physical parameters as empirical “predictors” of LCDU and pattern failures for the purpose of monitoring semiconductor manufacturing process characteristics, process window centering, process performance, and/or for other purposes.

These approaches provide empirical “models” that allow extrapolation of measured LCDU or failure rates to levels that are relevant for user process requirements. However, these models are based on CD measurements (i.e., individual measurements made along predefined cut lines) that generally do not provide adequate information about two-dimensional pattern shapes. Moreover, these models does not have predictive capabilities for any specified varying process parameters, or for new or different pattern types and shapes that were not used for model fitting or calibration.

Stochastic simulation using a Monte-Carlo approach has been included in rigorous commercially available lithography simulation packages, and proven valuable in process and patterning exploration. However, these simulators cannot handle large-scale or full-chip pattern layouts, due to runtime constraints, and/or for other reasons.

Prior semi-empirical stochastic edge placement (SEPE) models are not sufficiently accurate. These models derive specific parameters (e.g., image log slope), from simulated aerial images and fit these derived parameters against measured LCDU values during calibration. However, in practice, there is no rigorous definition of “aerial image” (or blurred aerial image, or latent image) or where exactly and correctly to evaluate image slope.

On the other hand, generally, an aerial image includes enough information enabling prediction or otherwise determination of stochastic effects. To address these and other disadvantages of prior models, the present disclosure provides a new method for predicting (and/or a system configured to predict) substrate geometry associated with a patterning process. The method comprises receiving input information including geometry information and/or process information for a pattern; and predicting, using a machine learning prediction model, multi-dimensional output substrate geometry based on the input information. In some embodiments, the predicting comprises determining an edge placement error (EPE) metric associated with one or more features of the pattern based on the input information and/or the output substrate geometry. In some embodiments, a machine-learning based prediction model is configured to take simulated aerial image intensity distributions and/or other information as input, and predicts two-dimensional pattern probability images (PPI) and/or other information. In some embodiments, the simulated aerial image intensity distributions are generated from an aerial image simulation model.

Conventionally, pattern probability images can be generated from measurements made on a large number of scanning electron microscope (SEM) images, or large-field of view SEM images of repeated pattern arrays in physical substrates (e.g., semiconductor devices), in combination with contour extraction and contour stacking techniques. Embodiments of the present disclosure which can predict and/or otherwise determine pattern probability images comprising two-dimensional distributions of pattern variability (e.g., for an SEPE band), as well as pattern failure rates (e.g., in the form of gray scale maps aligned with target layout patterns, which may be described in a .GDS file, for example), and/or other information.

In some embodiments, a machine learning (e.g., a computational neural network) prediction model is trained by using simulated aerial images and corresponding measured (as described above) pattern probability images, and/or other information as described below. The simulated aerial images may be generated by using an aerial image simulation model based on known mask layouts, mask characteristics, scanner optics, resist film stack characteristics, simulated aerial image gray scale images aligned to .GDS layout patterns, and/or other information.

Embodiments of the present disclosure can advantageously provide prediction capability for full-chip simulation based applications (e.g., for critical pattern identification for lithography manufacturability checks (LMC), computational hotspot detection (CHD), pattern fidelity metrology (PFM), and/or other operations). Embodiments of the present disclosure can provide prediction capability for stochastic variability bands and/or total pattern variability, e.g., depending on how the model is trained. Embodiments of the present disclosure can advantageously provide prediction capability for stochastic pattern failure rates, including predictions at “below ppm” (parts per million) failure levels that cannot regularly be modeled (e.g., due to the large number of measurements required at such low failure rates for typical correlation in prior models). Embodiments of the present disclosure can advantageously be trained with, and make predictions for, aerial images simulated at different positions in the resist layer to capture resist profile effects and corresponding defect mechanisms that may be relevant with high numerical aperture (NA) EUV lithography. These example advantages are not intended to be limiting.

Another aspect of the present disclosure provides for using an edge placement error (EPE) metric for hotspot (e.g., improperly designed and/or manufactured portions of a device) detection and/or verification. Current process adjustments are made (e.g., made as part of design for manufacturing (DFM), lithography manufacturability check (LMC), and/or other design verification flows) based on various individual metrics used to detect hotspots. These metrics include critical dimension (CD) error, low contrast/high mask error enhancement factor (MEEF), process window (PW) bands, and/or other key performance indicators (KPIs). However, these and other individual KPIs generally do not correlate well with overall device yield (e.g., which is the ultimate goal of process development and optimization). Specifically, for example, individual CD and overlay measurements, as well as post optical proximity correction (OPC) or source mask optimization (SMO) manufacturability verification KPIs, have relatively little power to predict potential hot spots in a designed or manufactured device. If a hot spot is missed, a device may continue to be processed, only to be rejected at a later point in the manufacturing process.

Using these individual KPIs with relatively little power to predict hot spots may lead to lower layer and device yield (e.g., because potential manufacturing issues may not be identified if there are no/few predicted hot spots), and/or a need for more extensive on-wafer defect/hotspot inspection and verification, followed by more process optimization loops. Using these individual KPIs with relatively little power to predict hot spots may also lead to longer ramp-up times and costs including additional mask writing and lithography process optimization, among other disadvantages.

Embodiments of the present disclosure provide a wholistic EPE metric that is advantageously and significantly more indicative of overall layer and device yield compared to prior KPIs, and can be used to more efficiently predict and/or detect hotspots. The EPE metric may be determined based on a combination of EPE contributors including global and local CD errors, expected local and global pattern displacement (overlay error+local placement error (LPE)), and/or other factors.

Embodiments of the present disclosure are described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “projection optics,” as used herein, should be broadly interpreted as encompassing various types of optical systems, including refractive optics, reflective optics, apertures and catadioptric optics, for example. The term “projection optics” may also include components operating according to any of these design types for directing, shaping, or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting, and/or projecting radiation from the source before the radiation passes the (e.g., semiconductor) patterning device, and/or optical components for shaping, adjusting, and/or projecting the radiation after the radiation passes the patterning device. The projection optics generally exclude the source and the patterning device.

The (e.g., semiconductor) patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. The design rules may include and/or specify specific parameters, limits on and/or ranges for parameters, and/or other information. One or more of the design rule limitations and/or parameters may be referred to as a “critical dimension” (CD). A critical dimension of a device can be defined as the smallest width of a line or hole or the smallest space between two lines or two holes, or other features. Thus, the CD determines the overall size and density of the designed device. One of the goals in device fabrication is to faithfully reproduce the original design intent on the substrate (via the patterning device).

The term “mask” or “patterning device” as employed in this text may be broadly interpreted as referring to a generic semiconductor patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. An example of a programmable LCD array is given in U.S. Pat. No. 5,229,872, which is incorporated herein by reference.

As used herein, the term “patterning process” generally means a process that creates an etched substrate by the application of specified patterns of light as part of a lithography process. However, “patterning process” can also include plasma etching, as many of the features described herein can provide benefits to forming printed patterns using plasma processing.

As used herein, the term “target pattern” means an idealized pattern that is to be etched on a substrate.

As used herein, the term “printed pattern” means the physical pattern on a substrate that was etched based on a target pattern. The printed pattern can include, for example, troughs, channels, depressions, edges, or other two and three dimensional features resulting from a lithography process.

As used herein, the term “prediction model” and/or “process model” (which may be used interchangeably) means a model that includes one or more models that simulate a patterning process.

For example, a prediction and/or process model can include an optical model (e.g., that models a lens system/projection system used to deliver light in a lithography process and may include modelling the final optical image of light that goes onto a photoresist), a resist model (e.g., that models physical effects of the resist, such as chemical effects due to the light), and an OPC model (e.g., that can be used to make target patterns and may include sub-resolution resist features (SRAFs), etc.), and/or other models.

As used herein, the term “calibrating” means to modify (e.g., improve or tune) and/or validate something, such as the process model.

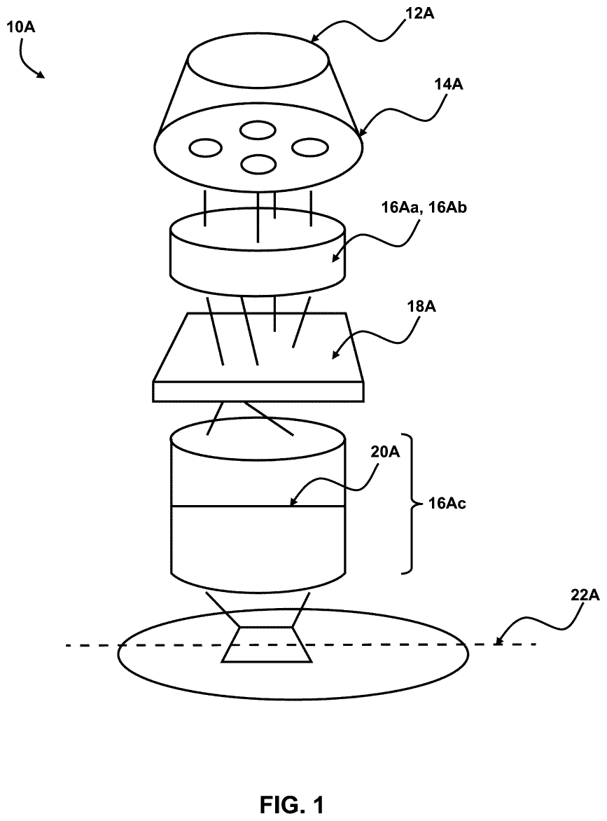

As an introduction, FIG. 1 illustrates a diagram of various subsystems of an example lithographic projection apparatus 10A. Major components are a radiation source 12A, which may be a deep-ultraviolet excimer laser source or other type of source including an extreme ultra violet (EUV) source (as discussed above, the lithographic projection apparatus itself need not have the radiation source), illumination optics which, for example, define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(θₘₐₓ), wherein n is the refractive index of the media between the substrate and the last element of the projection optics, and θₘₐₓ is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related to properties of the resist layer (e.g., effects of chemical processes which occur during exposure, post-exposure bake (PEB) and development). Optical properties of the lithographic projection apparatus (e.g., properties of the illumination, the patterning device, and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

It may be desirable to use one or more tools to produce results that, for example, can be used to design, control, monitor, etc. the patterning process. One or more tools used in computationally controlling, designing, etc. one or more aspects of the patterning process, such as the pattern design for a patterning device (including, for example, adding sub-resolution assist features or optical proximity corrections), the illumination for the patterning device, etc., may be provided. Accordingly, in a system for computationally controlling, designing, etc. a manufacturing process involving patterning, the manufacturing system components and/or processes can be described by various functional modules and/or models. In some embodiments, one or more electronic (e.g., mathematical, parameterized, etc.) models may be provided that describe one or more steps and/or apparatuses of the patterning process. In some embodiments, a simulation of the patterning process can be performed using one or more electronic models to simulate how the patterning process forms a patterned substrate using a design pattern provided by a patterning device.

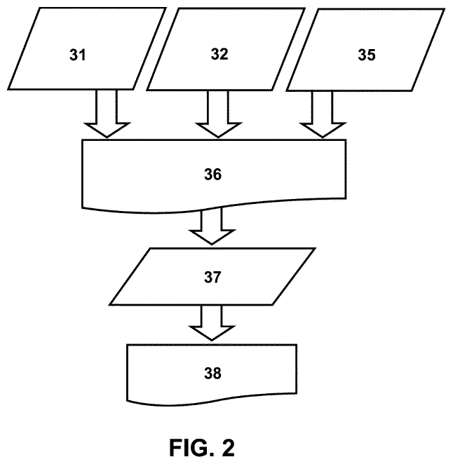

An exemplary flow chart for simulating lithography in a lithographic projection apparatus is illustrated in FIG. 2. An illumination model 31 represents optical characteristics (including radiation intensity distribution and/or phase distribution) of the illumination. A projection optics model 32 represents optical characteristics (including changes to the radiation intensity distribution and/or the phase distribution caused by the projection optics) of the projection optics. A design layout model 35 represents optical characteristics (including changes to the radiation intensity distribution and/or the phase distribution caused by a given design layout) of a design layout, which is the representation of an arrangement of features on or formed by a patterning device. An aerial image 36 can be simulated using the illumination model 31, the projection optics model 32, and the design layout model 35. A resist image 38 can be simulated from the aerial image 36 using a resist model 37. Simulation of lithography can, for example, predict contours and/or CDs in the resist image.

More specifically, illumination model 31 can represent the optical characteristics of the illumination that include, but are not limited to, NA-sigma (a) settings as well as any particular illumination shape (e.g. off-axis illumination such as annular, quadrupole, dipole, etc.). The projection optics model 32 can represent the optical characteristics of the of the projection optics, including, for example, aberration, distortion, a refractive index, a physical size or dimension, etc. The design layout model 35 can also represent one or more physical properties of a physical patterning device, as described, for example, in U.S. Pat. No. 7,587,704, which is incorporated by reference in its entirety. Optical properties associated with the lithographic projection apparatus (e.g., properties of the illumination, the patterning device, and the projection optics) dictate the aerial image. Since the patterning device used in the lithographic projection apparatus can be changed, it is desirable to separate the optical properties of the patterning device from the optical properties of the rest of the lithographic projection apparatus including at least the illumination and the projection optics (hence design layout model 35).

The resist model 37 can be used to calculate the resist image from the aerial image, an example of which can be found in U.S. Pat. No. 8,200,468, which is hereby incorporated by reference in its entirety. The resist model is typically related to properties of the resist layer (e.g., effects of chemical processes which occur during exposure, post-exposure bake and/or development).

The objective of the simulation is to accurately predict, for example, edge placements, aerial image intensity slopes and/or CDs, which can then be compared against an intended design. The intended design is generally defined as a pre-OPC design layout which can be provided in a standardized digital file format such as GDS, GDSII, OASIS, or other file formats.

From the design layout, one or more portions may be identified, which are referred to as “clips.” In an embodiment, a set of clips is extracted, which represents the complicated patterns in the design layout (typically about 50 to 1000 clips, although any number of clips may be used). As will be appreciated by those skilled in the art, these patterns or clips represent small portions (e.g., circuits, cells, etc.) of the design and especially the clips represent small portions for which particular attention and/or verification is needed. In other words, clips may be the portions of the design layout or may be similar or have a similar behavior of portions of the design layout where critical features are identified either by experience (including clips provided by a customer), by trial and error, or by running a full-chip simulation. Clips often contain one or more test patterns or gauge patterns. An initial larger set of clips may be provided a priori by a customer based on known critical feature areas in a design layout which require particular image optimization. Alternatively, in another embodiment, the initial larger set of clips may be extracted from the entire design layout by using an automated (such as, machine vision) or manual algorithm that identifies the critical feature areas.

For example, the simulation and modeling can be used to configure one or more features of the patterning device pattern (e.g., performing optical proximity correction), one or more features of the illumination (e.g., changing one or more characteristics of a spatial/angular intensity distribution of the illumination, such as change a shape), and/or one or more features of the projection optics (e.g., numerical aperture, etc.). Such configuration can be generally referred to as, respectively, mask optimization, source optimization, and projection optimization. Such optimization can be performed on their own, or combined in different combinations. One such example is source-mask optimization (SMO), which involves the configuring of one or more features of the patterning device pattern together with one or more features of the illumination. The optimization techniques may focus on one or more of the clips. The optimizations may use the machine learning model described herein to predict values of various parameters (including images, etc.).

In some embodiments, an optimization process of a system may be represented as a cost function. The optimization process may comprise finding a set of parameters (design variables, process variables, etc.) of the system that minimizes the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics. The cost function can also be the maximum of these deviations (i.e., worst deviation). The term “evaluation points” should be interpreted broadly to include any characteristics of the system or fabrication method. The design and/or process variables of the system can be confined to finite ranges and/or be interdependent due to practicalities of implementations of the system and/or method. In the case of a lithographic projection apparatus, the constraints are often associated with physical properties and characteristics of the hardware such as tunable ranges, and/or patterning device manufacturability design rules. The evaluation points can include physical points on a resist image on a substrate, as well as non-physical characteristics such as dose and focus, for example.

In a lithographic projection apparatus, as an example, a cost function may be expressed as

$$CF ( {z}_{1} , {z}_{2} , ⋯ , {z}_{N} ) = {\sum }_{p = 1}^{P} {w}_{p} {f}_{p}^{2} ( {z}_{1} , {z}_{2} , ⋯ , {z}_{N} )$$

where (z₁, z₂, . . . , z_{N}) are N design variables or values thereof, and fₚ(z₁, z₂, . . . , z_{N}) can be a function of the design variables (z₁, z₂, . . . , z_{N}) such as a difference between an actual value and an intended value of a characteristic for a set of values of the design variables of (z₁, z₂, . . . , z_{N}). In some embodiments, wₚ is a weight constant associated with fₚ(z₁, z₂, . . . , z_{N}). For example, the characteristic may be a position of an edge of a pattern, measured at a given point on the edge. Different fₚ(z₁, z₂, . . . , z_{N}) may have different weight wₚ. For example, if a particular edge has a narrow range of permitted positions, the weight wₚ for the fₚ(z₁, z₂, . . . , z_{N}) representing the difference between the actual position and the intended position of the edge may be given a higher value. fₚ(z₁, z₂, . . . , z_{N}) can also be a function of an interlayer characteristic, which is in turn a function of the design variables (z₁, z₂, . . . , z_{N}). Of course, CF(z₁, z₂, . . . , z_{N}) is not limited to the form in the equation above and CF(z₁, z₂, . . . , z_{N}) can be in any other suitable form.

The cost function may represent any one or more suitable characteristics of the lithographic projection apparatus, lithographic process, or the substrate, for instance, focus, CD, image shift, image distortion, image rotation, stochastic variation, throughput, local CD variation, process window, an interlayer characteristic, or a combination thereof. In some embodiments, the cost function may include a function that represents one or more characteristics of the resist image. For example, fₚ(z₁, z₂, . . . , z_{N}) can be simply a distance between a point in the resist image to an intended position of that point (i.e., edge placement error EPEₚ(z₁, z₂, . . . , z_{N}). The parameters (e.g., design variables) can include any adjustable parameter such as an adjustable parameter of the source, the patterning device, the projection optics, dose, focus, etc.

The parameters (e.g., design variables) may have constraints, which can be expressed as (z₁, z₂, . . . , z_{N})∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. Constraints should not be interpreted as a necessity. For example, the throughput may be affected by the pupil fill ratio. For some illumination designs, a low pupil fill ratio may discard radiation, leading to lower throughput. Throughput may also be affected by the resist chemistry. Slower resist (e.g., a resist that requires higher amount of radiation to be properly exposed) leads to lower throughput.

In some embodiments, illumination model 31, projection optics model 32, design layout model 35, resist model 37, and/or other models associated with and/or included in an integrated circuit manufacturing process may be an empirical model that performs the operations of the method described herein. The empirical model may predict outputs based on correlations between various inputs (e.g., one or more characteristics of a mask or wafer image, one or more characteristics of a design layout, one or more characteristics of the patterning device, one or more characteristics of the illumination used in the lithographic process such as the wavelength, etc.).

As an example, the empirical model may be a machine learning model and/or any other parameterized model. In some embodiments, the machine learning model (for example) may be and/or include mathematical equations, algorithms, plots, charts, networks (e.g., neural networks), and/or other tools and machine learning model components. For example, the machine learning model may be and/or include one or more neural networks having an input layer, an output layer, and one or more intermediate or hidden layers. In some embodiments, the one or more neural networks may be and/or include deep neural networks (e.g., neural networks that have one or more intermediate or hidden layers between the input and output layers).

As an example, the one or more neural networks may be based on a large collection of neural units (or artificial neurons). The one or more neural networks may loosely mimic the manner in which a biological brain works (e.g., via large clusters of biological neurons connected by axons). Each neural unit of a neural network may be connected with many other neural units of the neural network. Such connections can be enforcing or inhibitory in their effect on the activation state of connected neural units. In some embodiments, each individual neural unit may have a summation function that combines the values of all its inputs together. In some embodiments, each connection (or the neural unit itself) may have a threshold function such that a signal must surpass the threshold before it is allowed to propagate to other neural units. These neural network systems may be self-learning and trained, rather than explicitly programmed, and can perform significantly better in certain areas of problem solving, as compared to traditional computer programs. In some embodiments, the one or more neural networks may include multiple layers (e.g., where a signal path traverses from front layers to back layers). In some embodiments, back propagation techniques may be utilized by the neural networks, where forward stimulation is used to reset weights on the “front” neural units. In some embodiments, stimulation and inhibition for the one or more neural networks may be freer flowing, with connections interacting in a more chaotic and complex fashion. In some embodiments, the intermediate layers of the one or more neural networks include one or more convolutional layers, one or more recurrent layers, and/or other layers.

The one or more neural networks may be trained (i.e., whose parameters are determined) using a set of training information. The training information may include a set of training samples. Each sample may be a pair comprising an input object (typically a vector, which may be called a feature vector) and a desired output value (also called the supervisory signal). A training algorithm analyzes the training information and adjusts the behavior of the neural network by adjusting the parameters (e.g., weights of one or more layers) of the neural network based on the training information. For example, given a set of N training samples of the form {(x₁,y₁), (x₂,y₂), . . . , (x_{N},y_{N})} such that xᵢ is the feature vector of the i-th example and yᵢ is its supervisory signal, a training algorithm seeks a neural network g: X→Y, where X is the input space and Y is the output space. A feature vector is an n-dimensional vector of numerical features that represent some object (e.g., a simulated aerial image, a wafer design, a clip, etc.). The vector space associated with these vectors is often called the feature space. After training, the neural network may be used for making predictions using new samples.

An exemplary method according to an embodiment of the present disclosure comprises: receiving input information including geometry information and/or process information for a pattern; and predicting, using a machine learning prediction model, multi-dimensional output substrate geometry based on the input information. The predicting comprises determining an edge placement error (EPE) metric associated with one or more features of the pattern based on the input information, and predicting the multi-dimensional output substrate geometry based on the EPE metric. The present machine learning prediction model is calibrated (e.g., trained) with training information. The training information may include simulated aerial images associated with a pattern (e.g., a target design, a calibration pattern, and/or other patterns) and corresponding measured (as described above) pattern probability images, and/or other information. The training information may also include mask layouts, mask characteristics, scanner optics, resist film stack characteristics, simulated aerial image gray scale images aligned to .GDS layout patterns, and/or other information. For example, calibration (training) may include obtaining simulated aerial images associated with a pattern (e.g., that is to be printed on a wafer or portion thereof). From the images, contours (e.g., shapes, dimensions, etc.) can be extracted that correspond to features of the pattern. The features may be used by the machine learning prediction model to predict corresponding pattern probability images. Model parameters may be adjusted (or learned) such that the predicted pattern probability images more accurately match the measured pattern probability images (e.g., included in the training information). A calibrated (e.g., trained) model may be used to make new predictions (e.g., predict new pattern probability images) based on different (predicted) aerial images and/or other information used as input for the model.

In some embodiments, exemplary system(s) and method(s) provide a machine-learning based prediction model that takes simulated aerial image intensity distributions from an established aerial image simulation model and/or other information as input and predicts two-dimensional pattern probability images (PPI) and/or other information. Embodiments of the present disclosure may predict and/or otherwise determine pattern probability images comprising two-dimensional distributions of pattern variability (e.g., for an SEPE band), as well as pattern failure rates, and/or other information.

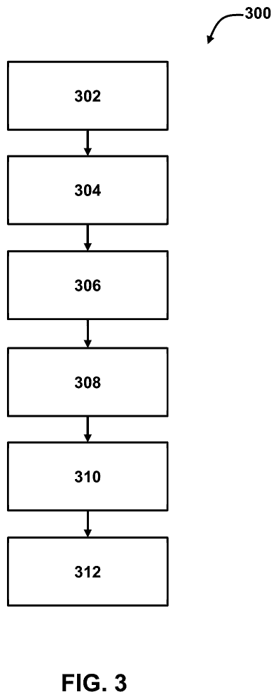

FIG. 3 illustrates an exemplary method 300 according to an embodiment of the present disclosure. In some embodiments, method 300 comprises training 302 the machine learning prediction model, receiving 304 input information, predicting 306 multi-dimensional output substrate geometry, and performing 308 LMC, PFM, and/or other process monitoring operations. In some embodiments, the multi-dimensional output substrate geometry is indicative of features in a substrate in a semiconductor device, and the patterning process comprises a semiconductor device manufacturing process. In some embodiments, method 300 includes adjusting 310 manufacturing process parameters and/or a manufacturing apparatus based on predictions from the model, tuning 312 the machine learning prediction model, and/or other operations. The operations of method 300 presented below are intended to be illustrative. In some embodiments, method 300 may be accomplished with one or more additional operations not described, and/or without one or more of the operations discussed. For example, operations 308, 310, 312, and/or other operations may be optional. Additionally, the order in which the operations of method 300 are illustrated in FIG. 3 and described below is not intended to be limiting. For example, method 300 may or may not include operations 308, 310, and/or 312.

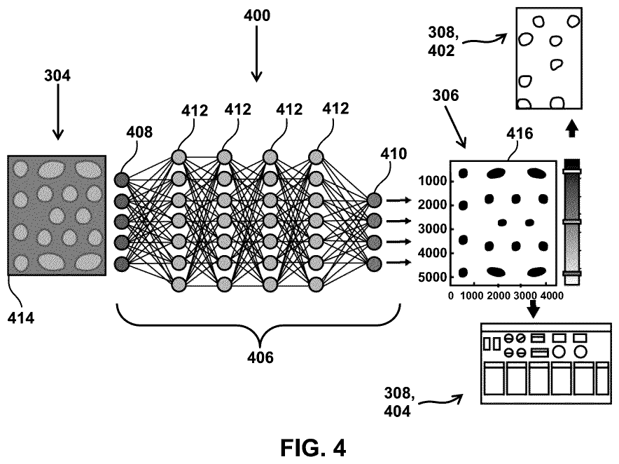

By way of a non-limiting overview example, FIG. 4 illustrates an exemplary process flow including receiving 304 input information, predicting 306 multi-dimensional output substrate geometry using a machine learning prediction model 400, and performing 308 LMC 402 and/or PFM 404. In some embodiments, the predicted multi-dimensional output substrate geometry comprises one or more pattern probability images, and/or other indications of the probability that given geometry of a given feature occupies a given location on a substrate. In some embodiments, the pattern probability image comprises a plurality of stacked images comprising predicted probabilities of two-dimensional substrate geometry for one or more vias, for example.

In some embodiments, as shown in FIG. 4, machine learning prediction model 400 comprises a (deep) neural network 406 and/or other components. Neural network 406 includes an input layer 408, an output layer 410, and a plurality of hidden layers 412 (this neural network design is not intended to be limiting). Neural network 406 may function as a geometry probability model, or a defect probability model, because the multi-dimensional output substrate geometry predicted by neural network 406 may include a pattern probability image 416 and/or other information. Pattern probability image 416 may be used to predict and/or otherwise determine a stochastic edge placement error band, presence of defects, a defect rate, and/or other information as described below. In the example shown in FIG. 4, the input information includes a simulated aerial image 414. However, the input information may include other information such as mask data, scanner data, simulated resist images, and other information as described herein. Details related to operations 304, 306, and 308 are further described below.

Returning to FIG. 3, at an operation, the machine learning prediction model is trained 302 (and may also be calibrated). The training information use for training the model may include pairs or sets of input objects and corresponding measured or desired output values. The training information may comprise one or more of aerial images, target patterns, or patterning process parameters, and corresponding physical substrate measurements and/or predictions from a different non-machine learning prediction model. The corresponding physical substrate measurements and/or predictions from a different non-machine learning prediction model comprise training (e.g., previously determined) pattern probability images, and/or other information. For example, in the present machine learning prediction model, the training information includes simulated aerial images associated with a pattern (e.g., a target design, a calibration pattern, and/or other patterns) and corresponding measured (as described above) pattern probability images, and/or other information. The training information may also include mask layouts, mask characteristics, scanner optics parameters, resist film stack characteristics, simulated aerial image gray scale images aligned to.GDS layout patterns, and/or other information. By way of a non-limiting example, training may include obtaining pairs of simulated aerial images and corresponding measured pattern probability images. The pairs may be provided to the machine learning prediction model as training information. The machine learning prediction model may self-learn (e.g., when the model is or includes a neural network as shown in FIG. 4) using the provided pairs of training information. A trained machine learning prediction model may be used to make new predictions (e.g., predict new pattern probability images) based on different input information such as different (predicted) aerial images and/or other information as described above.

At an operation, (e.g., new, or different information relative to the training information) input information is received 304 by the machine learning prediction model. The input information includes geometry information, process information, and/or other information. The process information comprises one or more parameters for one or more manufacturing processes performed for manufacturing a semiconductor device, and/or other information. The one or more parameters may be associated with different processing operations, forming features of a pattern on a substrate, adding or removing material from a substrate or a layer, and/or other operations performed for fabrication of a semiconductor device, and/or other information. The geometry information comprises dimensions, a design, a spatial orientation, and/or other geometrical characteristics for one or more features of one or more patterns associated with the semiconductor device, and/or other information. The input information is received by the machine learning prediction model as input for generating a prediction. For example, the input information may comprise one or more of a simulated aerial image, a simulated resist image, target feature dimensions, data from a scanner associated with semiconductor device manufacturing, mask layouts, mask characteristics, scanner optics parameters, resist film stack characteristics, and/or other information for a semiconductor device.

In some embodiments, as described above, the input information comprises a simulated aerial image. An aerial image may be used as input information because an aerial image includes pattern specific sensitivities that correlate to LCDU, defects in individual pattern features, and other information. Pattern specific sensitivities may refer to different patterns, or different pattern features, that may have different probabilities of becoming defects, or causing a large variability in CD (LCDU) due to the shapes of the pattern or a pattern feature, neighboring patterns, etc. In some embodiments, the input information comprises a plurality of aerial images, where individual aerial images of the plurality of aerial images correspond to different heights in resist layers. Such images may facilitate prediction of resist profiles, resist profile effects, and/or other information.

At an operation 306, the multi-dimensional output substrate geometry is predicted by the machine learning prediction model. The multi-dimensional output substrate geometry is predicted based on the input information, and/or other information. The multi-dimensional output substrate geometry indicates predicted multi-dimensional variability in shapes of features of the pattern in a substrate. The predicted multi-dimensional output substrate geometry indicates a probability that given geometry of a given feature occupies a given location on a substrate. In some embodiments, the predicted multi-dimensional output substrate geometry comprises one or more pattern probability images, and/or other indications of the probability that given geometry of a given feature occupies a given location on a substrate.

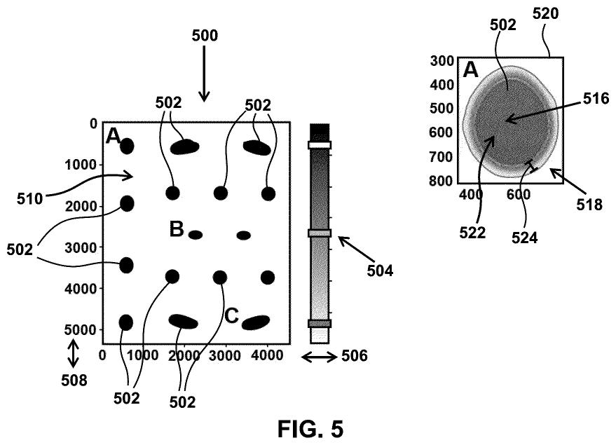

For example, FIG. 5 illustrates a predicted pattern probability image 500. Pattern probability image 500 comprises predicted two-dimensional substrate geometry for one or more features of a pattern. In the example shown in FIG. 5, the features are a plurality of vias 502 (with three individual vias labeled A, B, and C), but this example is not intended to be limiting. Other examples of features may include vias with other shapes (e.g., rectangular or square), an array or random layout of features, a line space, a pillar, and/or other features. In some embodiments, a pattern probability image 500 illustrates one or more unit cells of a pattern having one or more pattern features (e.g., vias 502, an array or random layout of features, a line space, a pillar, and/or other features). In this example, vias 502 (which would extend down through the page) are shown at different coordinate 506, 508 locations in a given portion (e.g., the one or more unit cells) of a patterned substrate 510. Pattern probability image 500 represents a plurality (e.g., thousands) of predictions for the same one or more unit cells from different locations around the pattern stacked on top of each other, with corresponding ones of the one or more features of the pattern aligned (e.g., individual vias 502 in this example). Pattern probability image 500 is associated with a probability indicator 504. In this example, probability indicator 504 is represented as a shaded gradient bar, where darker shades indicate higher probability (but this example is not intended to be limiting). The shading in the gradient bar corresponds to shading in individual vias 502, such that darker shaded areas of vias 502 indicate a prediction that there is a higher probability that a via 502, or a portion of a via 502, will be present at that location in a manufactured semiconductor device, relative to other locations on substrate 510.

This is further illustrated in a view 520 of a portion of substrate 510 that includes via 502A. Via 502A in view 520 is generally oval shaped, with relatively dark shading 516 at or near a middle portion 522 of the oval. The dark shading 516 of via 502 extends outwardly from middle portion 522 of the oval, and then becomes progressively lighter across a band 524 at an outer edge of the oval. The dark shading 516 in middle portion 522 indicates a prediction that there is a higher probability that via 502A, or a portion of via 502A, will be present at that location in a manufactured semiconductor device. The progressively lighter shading in band 524 indicates a prediction that there is less and less probability that via 502A, or a portion of via 502A, will be present at that location in a manufactured semiconductor device. At a position 518 outside the oval, the white gradient color indicates a prediction that there is a zero or almost zero probability that a via 502, or a portion of a via 502, will be present at that location in a manufactured semiconductor device.

In this way, pattern probability image 500 indicates multi-dimensional variability in shapes of features (e.g., vias 502) of the pattern in substrate 510. For example, in addition to providing a predicted coordinate location in substrate 510 for via 502A (and the other vias and/or other features), the gradient shading (corresponding to different predicted probabilities) across band 524 at the edge of via 502A provides an indication of how the location of an edge of via 502A may vary across a pattern, and/or “down” or “up” through a substrate. This predicted probability gradient may be used to determine a stochastic edge placement error band, and/or other information for via 502, and/or other features. The predicted coordinate locations for vias 502 (for example) may be used to determine whether electrical contact between layers will be made as intended, or whether there will be a defect present instead.

According to embodiments of the present disclosure, an exemplary multi-dimensional output substrate geometry predicted by the machine learning prediction model can advantageously provide prediction capability even for very low stochastic pattern failure rates. These very low stochastic pattern failure rates may be associated with uncommon, or infrequent (but nonetheless important) types of pattern failures. These uncommon or infrequent types of pattern failure may occur so infrequently that a very few or no measurements or other data may be recorded for such defects during a typical manufacturing process. This means that any such measurements or other data are not available (or not enough data is available) to calibrate prior models, and thus the prior models cannot accurately predict these uncommon or infrequent failure types.

Because the exemplary model is a machine learning prediction model, it can better predict these uncommon or infrequent types of pattern failure rates. The machine learning prediction model learns what features of the input information correlate to failures, and whether a failure is common or uncommon, even if measurements or other data describing a specific failure type are not available. For example, uncommon or infrequent types of pattern defects may be hidden in the tails of multi-dimensional output substrate geometry (probability) prediction distributions. The tails of multi-dimensional output substrate geometry (probability) prediction distributions may correspond to feature edges, and/or other locations, for example. In some embodiments, the machine learning prediction model is configured to make predictions for the probable locations of features and/or feature edges in a pattern based on a non-linear scale.

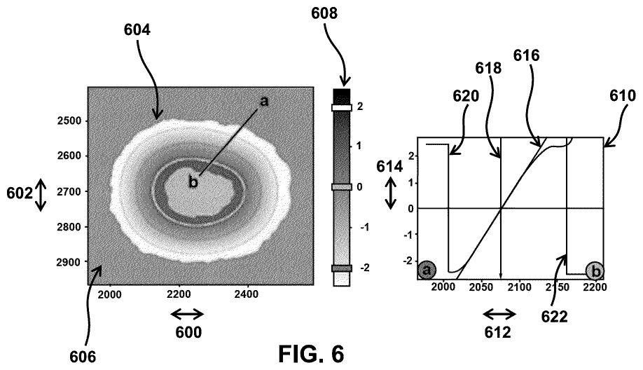

Making predictions based on a non-linear scale is illustrated in FIG. 6. FIG. 6 illustrates a portion of a predicted pattern probability image 604 with a predicted coordinate 600, 602 location of a via in pattern probability image 604 (this example is not intended to be limiting) in a substrate 606. FIG. 6 illustrates a probability indicator 608. In this example, probability indicator 608 comprises a shaded gradient bar, where darker shades indicate higher probability (again, this example is not intended to be limiting). The shading in the gradient bar corresponds to shading in the via in pattern probability image 604, such that darker shaded areas of pattern probability image 604 indicate a prediction that there is a higher probability that the via, or a portion of the via, will be present at that location in a manufactured semiconductor device, relative to other locations on substrate 606 (with the exception of area “b” in this example, as described below).

FIG. 6 also illustrates area “a” at or near an outer edge of pattern probability image 604, and an area “b” at or near a center of pattern probability image 604. Areas a and b are also shown in graphical representation 610. Graphical representation 610 illustrates location 612 in the portion of the predicted pattern probability image 604 and a vertical axis 614 showing a number of standard deviations from a median distribution value (0=the median, with 1 and −1, and 2 and −2 showing a number of standard deviations from the mean). Line 616 indicates a normal distribution, line 618 illustrates a median predicted feature edge location, and lines 620 and 622 illustrate extreme values for predicted feature edge locations. As shown in representation 610, areas a and b are located at extreme ends of the probability predictions for locations in pattern probability image 604. In some embodiments, the machine learning prediction model is configured to make predictions for the probable locations of edges in or near areas a and b, and/or other areas of pattern probability image 604 as described above. In some embodiments, the machine learning prediction model may determine that a predicted edge of a particular feature is relatively far from a normal/typical /nominal/previously predicted location for a feature edge (e.g., line 618), and extrapolate the results further to predict even lower probability feature locations than SEM tools can measure. In some embodiments, the machine learning prediction model is trained with log scale data to facilitate the prediction of the lower probability feature locations. For example, training pattern probability images may be converted to a log scale (e.g., 10\hat{ }N to N) and input into the model. Thus, corresponding output from the model may also be on a log scale. To make a failure rate determination, predictions from the model may be post-processed back to linear scale (e.g., N→10\hat{ }N).

Returning to FIG. 3, in some embodiments, operation 306 includes predicting and/or otherwise determining, with the machine learning prediction model, an edge placement error (EPE) metric, and/or other information. In some embodiments, an EPE metric may be a wholistic indication of edge placement error that is more predictive of overall layer and device yield compared to other key performance indicators (see detailed discussion of the EPE metric below). The EPE metric may be and/or include a single parameter such a value for an edge placement error, a stochastic edge placement error band (SEPE), and/or other single parameters. The EPE metric may also be and/or include a combination of such parameters, and/or other indications. The EPE metric may also be derived from the 2D pattern probability images in any direction to characterize possible failure modes in corresponding directions. A more detailed discussion of the EPE metric follows below. In some embodiments, operation 306 includes determining the EPE metric associated with one or more features of a pattern based on the input information, the multidimensional output substrate geometry, and/or other information. In some embodiments operation 306 includes predicting and/or otherwise determining, a stochastic failure rate, and/or other information.

By way of a non-limiting example, the predicted probabilities of the locations of various features of a pattern in a substrate (e.g., represented by the gradient shading of features) in a pattern probability image may be used to determine whether a feature (e.g., a via), or a portion of a feature, will be present at a given location in a manufactured semiconductor device. The probability that a feature will be present at a given location may be compared to a target design for a pattern, and/or compared to other information. Individual defects (e.g., a feature or portion of a feature is likely present where it should not be, or not present where it should be), defect rates (e.g., a number of defects per a number of total features), and/or other information may be predicted and/or otherwise determined based on such comparisons. For example, defects may be detected responsive to predicted locations of features breaching threshold location criteria for the predicted locations. In addition, the gradient of probabilities (e.g., the shading corresponding to different predicted probabilities) at the edges of features provides an indication of how the location of an edge of a feature may vary across a pattern. This predicted probability gradient may be used to determine a stochastic edge placement error band, and/or other information for a feature of a pattern.

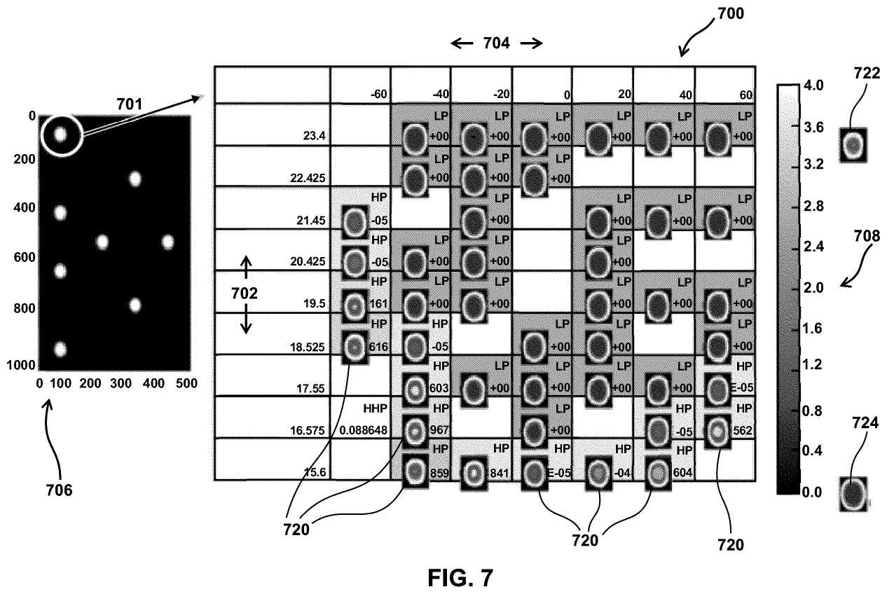

By way of another non-limiting example, FIG. 7 illustrates a defect probability map 700 predicted by an exemplary machine learning prediction model for various dose 702 and focus 704 conditions according to an embodiment of the present disclosure. FIG. 7 illustrates the predicted likelihood of a defect associated with a via 701 (as an example, other pattern features instead of and/or in addition to vias are contemplated). FIG. 7 illustrates a predicted pattern probability image 706. Pattern probability image 706 may be predicted based on a simulated aerial image and/or other information as described above. FIG. 7 also illustrates a predicted (probability) of a two-dimensional shape 720 of via 701 for each dose and focus combination (e.g., a pattern probability image for via 701 at each dose focus combination). Defect probability is indicated by the shading in probability bar 708, with lighter shading indicating higher defect probability. To aid in interpretation, boxes in FIG. 7 have also been labeled either LP (relatively low probability), HP (relatively higher probability), or HHP (highest probability).

Probability bar 708 also includes representative predicted (probabilities) of two-dimensional geometry of example vias for a likely defective via 722 and a likely non-defective via 724. FIG. 7 illustrates how different dose focus combination have different pattern probability images (e.g., for via 701), which represent different SEPE and failure rates. By taking part of these pattern probability images at different dose focus conditions to train the model, pattern probability images at other dose focus conditions may be predicted.

At an operation 308, LMC, PFM, and/or other process monitoring operations are performed. Operation 308 includes using a predicted pattern probability image (or images) for LMC, PFM, and/or other process monitoring operations in a semiconductor device manufacturing process. LMC and/or PFM may include checking a predicted pattern and/or predicted pattern dimensions for manufacturability and/or for other reasons. Checking a predicted pattern and/or pattern dimensions for manufacturability may include determining whether lithography and/or other manufacturing process operations are likely to produce a target design. This may include identifying critical patterns, portions of patterns, dimensions, and/or other characteristics of a design. In some embodiments, the output from the calibrated machine learning model may be feed into LMC for SEPE simulations.

In some embodiments, method 300 includes adjusting 310 semiconductor device manufacturing process parameters and/or a semiconductor device manufacturing apparatus. Adjusting the semiconductor device manufacturing process parameters may be the same as, and/or include, adjusting the semiconductor device manufacturing process. Adjustments may be made based on predictions from the model and/or other information. For example, manufacturing process parameters may be determined based on predictions from the prediction model, based on data from the LMC, PFM, and/or other process monitoring operations, and/or other information. Manufacturing process parameter adjustments may be determined (e.g., an amount a given parameter should be changed), and the manufacturing process parameters may be adjusted from prior parameter set points to new parameter set points, for example. An adjustment for the semiconductor device manufacturing apparatus may be determined based on the adjusted manufacturing process parameters, the predictions from the prediction model, the data from the process monitoring operations (e.g., LMC, PFM, etc.) and/or other information.

In some embodiments, the determined and/or adjusted semiconductor device manufacturing process parameters comprise one or more of a mask design, a pupil shape, a dose, a focus, etching parameters, deposition parameters, chemical mechanical polishing parameters, and/or other semiconductor device manufacturing process parameters. In some embodiments, the method comprises determining an adjustment for a semiconductor device manufacturing process and/or apparatus based on determined semiconductor device manufacturing parameters. As an example, if the process parameter were a (e.g., new) pupil shape, a dose, or a focus, the manufacturing apparatus could be adjusted from an old or previous pupil shape, dose, or focus, to the determined (e.g., new) pupil shape, dose, or focus. Similarly, if the manufacturing process parameter is a new or adjusted mask design, the semiconductor manufacturing apparatus could be adjusted based on this new design (e.g., one might adjust an intensity, an alignment, or even a pupil shape, dose, or focus based on new mask shapes, sizes, etc.) In some embodiments, the method may comprise adjusting the mask design from a first mask design to a second mask design based on the predictions from the prediction model, as another example.

In some embodiments, method 300 includes tuning 312 the machine learning prediction model, and/or other operations. In some embodiments, operation 312 includes tuning the machine learning prediction model such that the multi-dimensional output substrate geometry matches an EPE metric such as a measured stochastic edge placement error band or measured failure rate, for example. In some embodiments, operation 312 includes tuning the machine learning prediction model such that the multi-dimensional output substrate geometry corresponds to, or matches, a mean contour prediction from an optical proximity correction model or a lithography manufacturability check model, as another example. In some embodiments, the machine learning prediction model may be tuned and/or otherwise calibrated based on after development inspection dimensions, after etch inspection dimensions, and/or other information associated with another semiconductor device manufacturing process.

In some embodiments, tuning comprises adjusting one or more model parameters such that the predicted multi-dimensional output substrate geometry better matches, or better corresponds to, a measured stochastic edge placement error band measured failure rate, the mean contour prediction from an optical proximity correction model or a lithography manufacturability check model, the after development inspection dimensions, the after etch inspection dimensions, and/or other information. In some embodiments, tuning comprises training or re-training the machine learning prediction model using additional training information comprising new and/or additional measured stochastic edge placement error band or measured failure rate information, additional and/or new mean contour prediction information from an optical proximity correction model or a lithography manufacturability check model, new and/or additional after development inspection dimensions, new and/or additional after etch inspection dimensions, and/or other information.

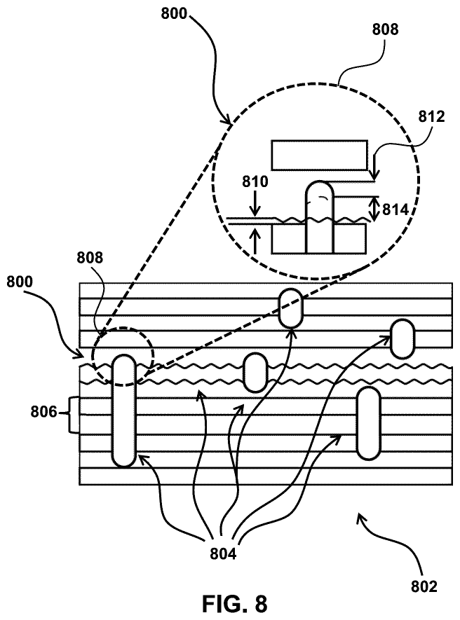

FIG. 8 illustrates edge placement error (EPE) 800. EPE 800 may refer to the relative displacement of an edge (of some feature in a pattern) from a target position. FIG. 8 illustrates a pattern 802 with various features 804 and a pitch 806. In FIG. 8, a portion 808 of pattern 802 is enlarged for easier viewing. Portion 808 illustrates EPE 800, which includes EPE for a line 810 and EPE for a cut 812 (along with intended overlap 814). As described herein, EPE 800 may include and/or be caused by global errors (e.g., CD, overlay), local errors (e.g., local critical dimension uniformity (LCDU), local placement error (LPE) which may include stochastic variations of a feature's center of gravity around a designed location for example, line edge roughness (LER) which may include high frequency stochastic variations of a one-dimensional feature's edge for example, contact (or cut) edge roughness (CER) which may include high frequency stochastic variations for a two dimension feature's (like a contact or cut) edges, etc.), systematic errors (e.g., from OPC, proximity bias average (PBA) which may describe a scanner to scanner mismatch (e.g., of through-pitch proximity curves) due to small differences in pupils, aberrations, etc.), and/or other factors. As described herein, the EPE metric is a wholistic EPE metric that is more predictive of overall layer and device yield compared to conventionally used KPIs, and can be used to better and more efficiently predict and/or detect hotspots. The EPE metric is determined based on a combination of major EPE contributors including the factors listed above, and/or other factors.

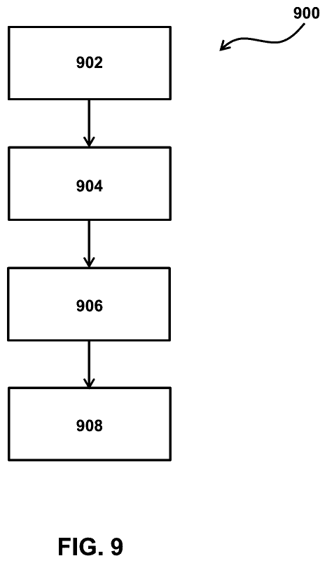

FIG. 9 illustrates an exemplary method 900 in accordance with an embodiment of the present disclosure. In some embodiments, method 900 comprises a manufacturing process. Method 900 provides a wholistic EPE metric that is more predictive of overall layer and device yield compared to KPIs used in the prior art, and can be used to better and more efficiently predict and/or detect hotspots. In some embodiments, method 900 comprises receiving 902 input information including geometry information and/or patterning process information for a pattern on a substrate, determining 904 an EPE metric associated with one or more features of the pattern based on the input information, determining 906 one or more areas of the pattern on the substrate that have one or more potential defects based on the EPE metric, determining 908 an adjustment for a semiconductor device manufacturing apparatus based on the one or more areas of the pattern on the substrate that have the one or more potential defects, and/or other operations.

The operations of method 900 described herein are intended to be illustrative. In some embodiments, method 900 may be accomplished with one or more additional operations not described, and/or without one or more of the operations discussed. For example, operation 908 and/or other operations may be optional. Additionally, the order in which the operations of method 900 are illustrated in FIG. 9 and described below is not intended to be limiting. Method 900 may be performed by one or more processors and/or other components that form at least a part of and/or are included in a computing system, a lithography apparatus, and/or other devices. The computing system and/or the lithography apparatus may be similar to and/or the same as the computing system(s) and/or the lithography apparatus(es) described herein, for example.

At operation 902, input information including geometry information and/or patterning process information for a pattern on a substrate is received. In some embodiments, the input information is measured and/or simulated results (e.g., using an electronic model as described herein). In some embodiments, the geometry information comprises one or more indications of a size and/or a position of one or more features of the pattern. For example, the geometry information may describe a target and/or actual dimensional layout of one or more features a pattern, alignment of one or more features in a pattern, sizes of one or more of the features, shapes of one or more of the features, and/or other information. Patterning process information may include an indication of which manufacturing processes have been or will be performed, set points and/or other parameters for manufacturing processes, and/or other information. In some embodiments, the input information comprises and/or is determined based on one or more of a predicted aerial image, target substrate dimensions, data from a scanner and/or patterning process associated with semiconductor device manufacturing, and/or other information for one or more layers of a semiconductor device. In some embodiments, the input information comprises one or more parameters including global overlay, a global critical dimension, a local critical dimension, a feature edge roughness (e.g., 1D (lines) and 2D (contact edge roughness) features), a local critical dimension uniformity, mask critical dimension, mask placement error, scanner to scanner critical dimension, scanner to scanner overlay mismatches, patterning tool critical dimension, patterning tool overlay mismatches, local and global variations of feature asymmetry (e.g., contact ellipticity variations including directional (angle) and long/short ellipse variations), a value indicative of an interaction/cross-talk between two or more of the parameters, and/or other information.

At operation 904, an EPE metric associated with one or more features of the pattern is determined. In operation 904, the EPE metric is determined based on the input information and/or other information. The EPE metric is correlated to a yield associated with the pattern on the substrate. The EPE metric may be better correlated to the yield, for example, compared to prior individual KPIs. In some embodiments, the EPE metric comprises a combination of two or more of the parameters and/or the values indicative of the interactions between two or more of the parameters in the input information. For example, the EPE metric may be a combination of global error parameters such as global CDU and overlay, local error parameters such as LCDU, local placement error (LPE), line edge roughness (LER), and/or CER, systematic error parameters in OPC and/or PBA, and/or other parameters.

EPE is usually constructed based on individual prior measurements of its components, but here, the EPE metric is determined based on measured and/or predicted EPE contributors. For example, the EPE metric may be determined based on the output from an FEM lithography model configured to predict global CD/edge and aberration-driven pattern shift errors using known scanner settings and their variations (e.g., in focus and leveling, dynamics, aberrations, laser bandwidth, pupil etc.) from a calibrated resist model; the impact of LCDU and other stochastic-related CD and pattern shift LER, LPE, etc., which can be predicted at a given probability level with simulated scanner contrast and a calibrated resist model, for example (where LCDU ∝1/NILS); expected global overlay error (with a given probability level), which may be obtained from scanner specifications, for example (measured and/or computational overlay (OVL) fingerprint maps may be used for existing scanners at customer sites); and/or other information.

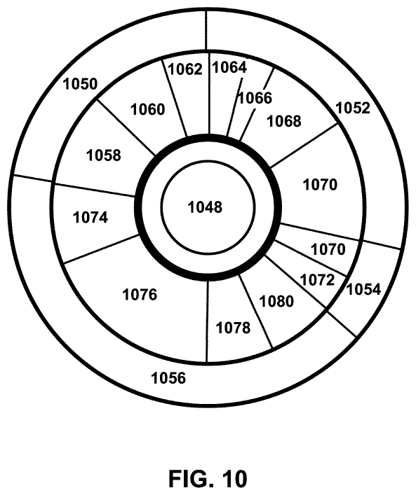

For example, FIG. 10 illustrates EPE contributors used to determine an EPE metric 1048. Some or all of the contributors, and/or the interactions between two or more of these contributors, may be used to determine the EPE metric. These EPE contributors may be included in the input information described above, for example. As shown in FIG. 10, the EPE contributors may include OPC CD (errors) 1050, overlay (errors) 1052, global CD 1054, and local CD (errors) 1056. OPC CD (errors) may be associated with a resist model 1058, an etch model 1060, the structure of a model itself and/or an associated run time 1062, and/or other factors. Overlay (errors) 1052 may be associated with a process mask 1064, metrology 1066, a scanner application 1068, a scanner itself 1070, and/or other factors. Global CD 1054 may be associated with scanner 1070, tracking and/or etching operations 1072, and/or other factors. Local CD (errors) 1056 may be associated with a mask 1074, resist and/or resist process control parameters 1076, SMO 1078, scanner optics and/or dynamics 1080, and/or other factors. Two or more of these EPE contributors, and/or interactions between two or more of these contributors, are combined together, to determine the EPE metric (e.g., a per-edge shift at a chosen probability level). For example, the EPE metric may be a combination of the global CD and OVL and local CD and OVL contributions using an actual post-OPC (or SMO etc.) pattern, with its actual OPC (errors). This example is not intended to be limiting.

In some embodiments, the EPE metric is mathematically calculated and/or predicted (e.g., using a prediction model as described herein) based on one or more of the parameters and/or the value indicative of the interaction between two or more of the parameters of the input information (e.g., the global error parameters, the local error parameters, the systematic error parameters, etc. as shown in FIG. 10). For example, the EPE metric may be mathematically calculated based on the equation:

$${EPE}_{max}^{*} = \frac{{HR}_{OPC}}{2} + \frac{3 {σ}_{PBA}}{2} + \frac{6 {σ}_{LWR}}{\sqrt{2}} + \sqrt{{( 3 {σ}_{OVL} )}^{2} + {( \frac{3 {σ}_{CDU}}{2} )}^{2}}$$

It should be noted that this is a simplified example formula for a contact-to-line use case (where the symbol for sigma represents a standard deviation of corresponding EPE contributors, EPEₘₐₓ represents a constructed EPE value, HR_{OPC} represents a half range of an OPC error, PBA represents proximity bias average error, LWR represents local CD effects, OVL represent overlay error, and CDU represents global CD variations). This equation does not cover all possible EPE metric contributors and use cases. Again, it is use case specific, simplified, and should be viewed as just one example of many possible equations within the scope of the present disclosure. A non-simplified mathematical calculation may be performed, for example, using extreme value statistics using additional process and/or device inputs such as feature redundancy, accepted failure rate, etc.

In some embodiments, one or more of the electronic models described herein comprise a computational lithography model (e.g., a computational neural network and/or some other computational lithography model). In some embodiments, determining the EPE metric comprises predicting the EPE metric using the input information and/or other input information as input to the computational lithography model. In some embodiments, the EPE metric is determined (e.g., by the computational lithography model) based on a target EPE probability level and/or other information. The target EPE probability level may be entered or selected by a user via a user interface (e.g., that is part of a computing device) or generated automatically by executing a computer implemented program. The target probability level may be defined or chosen based on an allowed number of defects per die (e.g., as determined by a user), per sub-die area like memory mat and/or per number of features (e.g. 1 per 10\hat{ }6). This level may be driven by designed feature redundancy (e.g., a design approach allowing some features to fail without making whole chip not functional), by a layer yield specification, and/or by other device, process, and/or yield related reasons.

Returning to FIG. 9, at an operation 906, one or more areas of the pattern on the substrate that have one or more potential defects are determined. The one or more areas are determined based on the EPE metric and/or other information. The one or more areas of the pattern on the substrate that have the one or more potential defects comprise hot spots.

In some embodiments, determining one or more areas of the pattern on the substrate that have one or more potential defects based on the EPE metric comprises determining a probability that a given feature of the pattern occupies a given location on the substrate. For example, based on per-edge shift estimations (e.g., as described above), feature contours at given error probability levels, and/or probability maps, may be constructed, based on predicted data (including expected OVL error).

In some embodiments, determining one or more areas of the pattern on the substrate that have one or more potential defects based on the EPE metric is based on a cost function that balances an acceptable defect probability with resources required to inspect the number of the one or more areas. In some embodiments, the acceptable defect probability is related to a number of the one or more areas of the pattern on the substrate that have the one or more potential defects that are targeted for inspection. In some embodiments, determining the one or more areas of the pattern on the substrate that have the one or more potential defects based on the EPE metric comprises determining a pattern probability image for one or more features of the pattern. The pattern probability image comprises predicted two-dimensional substrate geometry for one or more of the features (e.g., as described herein). The pattern probability image may include EPE bands determined based on corresponding EPE metrics, and/or other information, for example. An EPE band may indicate a likelihood that an edge of a feature of a pattern is in a certain range of locations on a substrate.

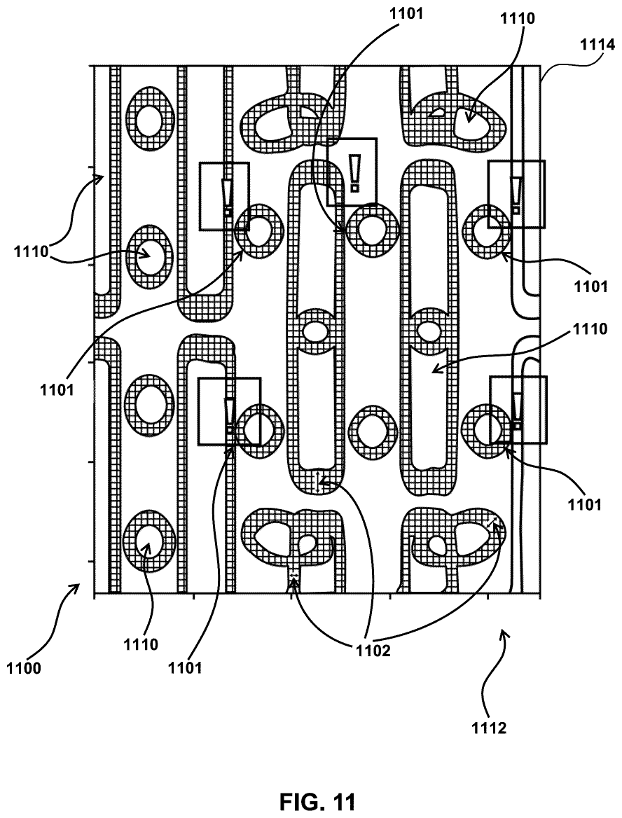

For example, FIG. 11 illustrates a pattern probability image 1100. Image 1100 may be predicted and/or otherwise determined as described above. Image 1100 illustrates features 1110 of a pattern 1112 on a substrate 1114. Image 1100 includes various overlapping 1101 EPE bands 1102 (another example of an EPE metric). EPE bands 1102 may be inspected for instances of feature bridging, necking etc. at a given probability threshold. The probability threshold may be determined based on (e.g., a customer's) maximum allowed defect rate, for example, and/or other information. In FIG. 11, areas with overlapping EPE (see the “!” in FIG. 11)) may be labeled as hotspots, examined, and fixed.

In some embodiments, an EPE metric (e.g., predicted and/or otherwise determined as described herein) may be symmetric or asymmetric for one or more features of a pattern. In some embodiments, a symmetric EPE metric may indicate substantially the same and/or an evenly distributed EPE metric on all sides, all the way around, and/or throughout the one or more features of a pattern relative to a median predicted EPE metric (e.g., the predicted location of the edge of a pattern feature, a predicted EPE band width, a stochastic edge placement error band, and/or other median predicted EPE metrics). In some embodiments, a symmetric EPE metric comprises an evenly distributed range of possible EPE metrics on either side of the median predicted EPE metric. For example, a probability that the edge of a feature is inside or outside a predicted location (e.g., an EPE metric) may vary equally as distance increases from the predicted location in opposite directions, when the predicted EPE metric is symmetric. In some embodiments, a symmetric EPE metric may have a Gaussian distribution. This means that a median EPE metric may be predicted (e.g., a median EPE), and the probability that the EPE metric (or the EPE) is actually greater or less than the median has a Gaussian distribution. Continuing with the example above, the probability that the edge of a feature is inside or outside a predicted location by 1 nm, 2 nm, 3 nm, etc. in either direction may be the same, when the predicted EPE metric is symmetric.

In some embodiments, an asymmetric EPE metric may indicate substantially a different and/or substantially unevenly distributed EPE metric on different sides, around, and/or throughout the one or more features of a pattern relative to a median predicted EPE metric (e.g., the predicted location of the edge of a pattern feature, a predicted EPE band width, a stochastic edge placement error band, and/or other median predicted EPE metrics). In some embodiments, an asymmetric EPE metric comprises an unevenly distributed range of possible EPE metrics on either side of the median predicted EPE metric. For example, a probability that the edge of a feature is inside or outside a predicted location (e.g., an EPE metric) may not vary equally as distance increases from the predicted location in opposite directions, when the predicted EPE metric is asymmetric. In some embodiments, an asymmetric EPE metric may have a non-Gaussian distribution. This means that a median EPE metric may be predicted (e.g., a median EPE), and the probability that the EPE metric (or the EPE) is actually greater or less than the median does not have a Gaussian distribution. Continuing with the example above, the probability that the edge of a feature is inside or outside a predicted location by 1 nm, 2 nm, 3 nm, etc. in either direction is not the same, when the predicted EPE metric is asymmetric. This asymmetry may not be limited to X or Y of the pattern, but also to any other angles.

It should be noted that, in some embodiments, the machine learning prediction model is trained using asymmetrically distributed training data such that weights and/or parameters of the trained machine learning prediction model facilitate determination of the symmetric or asymmetric EPE metric. In some embodiments, an asymmetric EPE metric may be determined based on asymmetrically distributed CD values and/or other information. In some embodiments, the asymmetrically distributed training data comprises asymmetrically distributed EPE metrics determined from multi-dimensional probability images associated with asymmetrically distributed CD values and/or other information. The asymmetrically distributed CD values indicate contour sizes from which CD values were measured are asymmetrically distributed. The edge placement of patterns are determined from the contours. As a result, the asymmetrically distributed EPE is related to the asymmetrically distributed CD values. Such images may be provided to the model as input training data, for example, as described above. Once trained, a machine learning model configured to predict and/or otherwise determine asymmetric EPE metrics may be used for lithography manufacturability checks, verification of optical proximity correction results, EPE metrology products, products that make predictions based on a CD distribution, and/or in any other application where printed dimensions of features of a pattern are predicted.

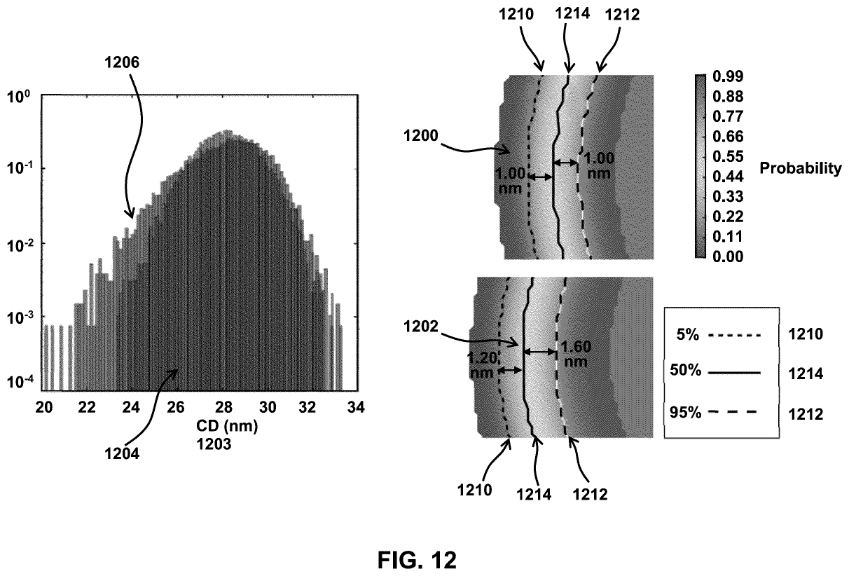

By way of a non-limiting example, FIG. 12 illustrates symmetric 1200 and asymmetric 1202 predicted or measured EPE (e.g., an example of an EPE metric). In some embodiments, symmetric EPE 1200 may be predicted with a machine learning model or directly measured with SEM metrology or otherwise determined based on one or more pattern probability images created from a Gaussian CD 1203 distribution 1204 and/or other information. In some embodiments, asymmetric EPE 1202 may be predicted with a machine learning model or directly measured with SEM metrology or otherwise determined based on pattern probability image created from a non-Gaussian CD 1203 distribution 1206 and/or other information. FIG. 12 illustrates 5% inner 1210 and 95% outer 1212 predicted or measured probability contours for an EPE relative to a median 1214. For symmetric EPE 1200, contours 1210 and 1212 are both located 1 nm from median 1214. For asymmetric EPE 1202, contours 1210 and 1212 are located at different distances from median 1214. For example, contour 1210 is located 1.6 nm from median 1214, while contour 1212 is located 1.2 nm from median 1214. This indicates how, in some embodiments, a symmetric EPE metric comprises an evenly distributed range of possible EPE metrics on either side of the median predicted EPE metric. In this example, a probability that the edge of a feature is inside or outside a predicted location (e.g., median 1214) may vary equally as distance increases from the predicted location in opposite directions, when the predicted EPE metric is symmetric. This also indicates how, in some embodiments, an asymmetric EPE metric comprises an unevenly distributed range of possible EPE metrics on either side of the median predicted EPE metric. For example, a probability that the edge of a feature is inside or outside a predicted location (e.g., median 1214) may not vary equally as distance increases from the predicted location in opposite directions, when the predicted EPE metric is asymmetric. The symmetric or asymmetric EPE can be derived from predicted or measured 2D pattern probability images. For a metrology use case, symmetric or asymmetric EPE is directly reported from the 2D pattern probability images. When applying the machine learning model, the symmetric or asymmetric EPE is reported from the predicted 2D pattern probability images. The 2D pattern probability images includes the symmetric or asymmetric EPE in a wide range of probabilities and along any directional cutline around the pattern.

Returning to FIG. 9, at operation 908, an adjustment for a semiconductor device manufacturing apparatus is determined based on the one or more areas of the pattern on the substrate that have the one or more potential defects. In some embodiments, operation 908 may include actually making the adjustment. The adjustment may be determined based on the one or more areas of the pattern on the substrate that have the one or more potential defects, and/or other information. For example, in some embodiments, receiving the input information (operation 902), determining the EPE metric (operation 904), and determining the one or more areas of the pattern on the substrate that have one or more potential defects (operation 906) are performed as part of an assessment, improvement, prediction, or verification of semiconductor device performance. The assessment, improvement, prediction, or verification of semiconductor device performance may comprise source mask optimization, optical proximity correction, a lithography manufacturability check, a design for manufacturing flow associated with a semiconductor device. The adjustment may be determined as a way to enhance a manufactured device. For example, the adjustment may comprise one or more of a change in the pattern, a change in a mask, a change of a dose, a change in a focus, a change in an exposure, a change in a pupil, a change in an etch and/or deposition process temperature, a change in an etch and/or deposition process time, and/or other adjustments. Any and/or all of these adjustments may be made in order to enhance a manufactured device, for example.

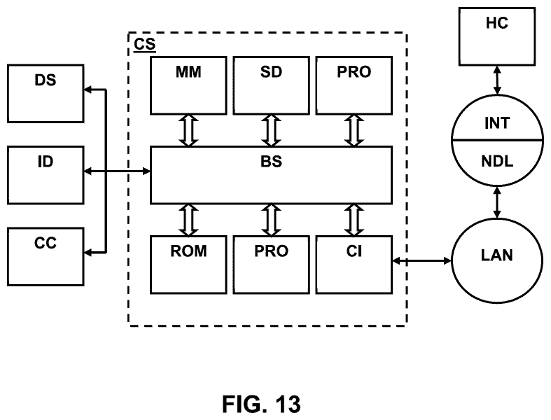

FIG. 13 is a diagram of an example computer system CS that may be used for one or more of the operations described herein. Computer system CS includes a bus BS or other communication mechanism for communicating information, and a processor PRO (or multiple processors) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic, or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic, or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

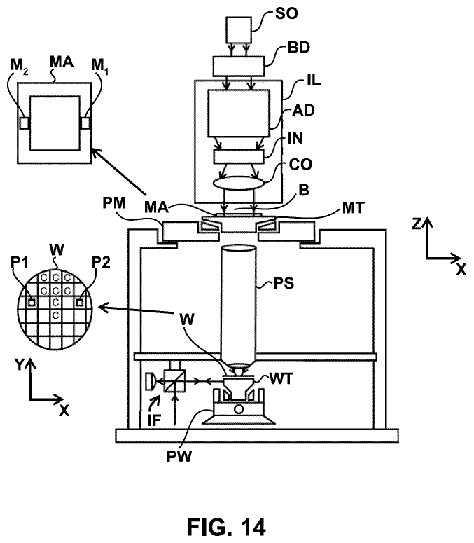

FIG. 14 is a schematic diagram of a lithographic projection apparatus, according to an embodiment. The lithographic projection apparatus can include an illumination system IL, a first object table MT, a second object table WT, and a projection system PS. Illumination system IL, can condition a beam B of radiation. In this example, the illumination system also comprises a radiation source SO. First object table (e.g., a patterning device table) MT can be provided with a patterning device holder to hold a patterning device MA (e.g., a reticle), and connected to a first positioner to accurately position the patterning device with respect to item PS. Second object table (e.g., a substrate table) WT can be provided with a substrate holder to hold a substrate W (e.g., a resist-coated silicon wafer), and connected to a second positioner to accurately position the substrate with respect to item PS. Projection system (e.g., which includes a lens) PS (e.g., a refractive, catoptric or catadioptric optical system) can image an irradiated portion of the patterning device MA onto a target portion C (e.g., comprising one or more dies) of the substrate W. Patterning device MA and substrate W may be aligned using patterning device alignment marks M1, M2 and substrate alignment marks P1, P2, for example.

As depicted, the apparatus can be of a transmissive type (i.e., has a transmissive patterning device). However, in general, it may also be of a reflective type, for example (with a reflective patterning device). The apparatus may employ a different kind of patterning device for a classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander, or beam delivery system BD (comprising directing mirrors, the beam expander, etc.). for example. The illuminator IL may comprise adjusting means AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus. The radiation beam that it produces may be led into the apparatus (e.g., with the aid of suitable directing mirrors), for example. This latter scenario can be the case when source SO is an excimer laser (e.g., based on KrF, ArF or F2 lasing), for example.

The beam B can subsequently intercept patterning device MA, which is held on a patterning device table MT. Having traversed patterning device MA, the beam B can pass through the lens PL, which focuses beam B onto target portion C of substrate W. With the aid of the second positioning means (and interferometric measuring means IF), the substrate table WT can be moved accurately, e.g. to position different target portions C in the path of beam B. Similarly, the first positioning means can be used to accurately position patterning device MA with respect to the path of beam B, e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool), patterning device table MT may be connected to a short stroke actuator, or may be fixed.

The depicted tool can be used in two different modes, step mode and scan mode. In step mode, patterning device table MT is kept essentially stationary, and an entire patterning device image is projected in one operation (i.e., a single “flash”) onto a target portion C. Substrate table WT can be shifted in the x and/or y directions so that a different target portion C can be irradiated by beam B. In scan mode, essentially the same scenario applies, except that a given target portion C is not exposed in a single “flash.” Instead, patterning device table MT is movable in a given direction (e.g., the “scan direction”, or the “y” direction) with a speed v, so that projection beam B is caused to scan over a patterning device image. Concurrently, substrate table WT is simultaneously moved in the same or opposite direction at a speed V=Mv, in which M is the magnification of the lens (typically, M=¼ or ⅕). In this manner, a relatively large target portion C can be exposed, without having to compromise on resolution.

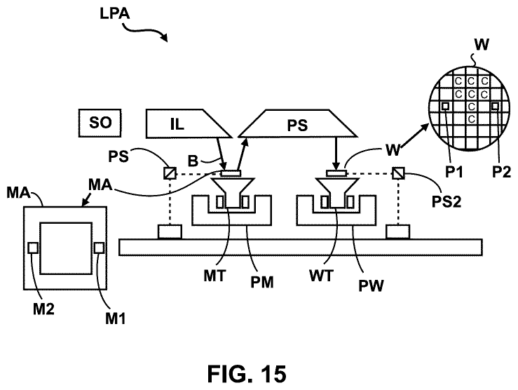

FIG. 15 is a schematic diagram of another lithographic projection apparatus (LPA) that may be used for, and/or facilitating one or more of the operations described herein. LPA can include source collector module SO, illumination system (illuminator) IL configured to condition a radiation beam B (e.g. EUV radiation), support structure MT, substrate table WT, and projection system PS. Support structure (e.g. a patterning device table) MT can be constructed to support a patterning device (e.g. a mask or a reticle) MA and connected to a first positioner PM configured to accurately position the patterning device. Substrate table (e.g. a wafer table) WT can be constructed to hold a substrate (e.g. a resist coated wafer) W and connected to a second positioner PW configured to accurately position the substrate. Projection system (e.g. a reflective projection system) PS can be configured to project a pattern imparted to the radiation beam B by patterning device MA onto a target portion C (e.g. comprising one or more dies) of the substrate W.

As shown in this example, LPA can be of a reflective type (e.g. employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultra violet radiation beam from source collector module SO. Methods to produce EUV radiation include, but are not necessarily limited to, converting a material into a plasma state that has at least one element, e.g., xenon, lithium, or tin, with one or more emission lines in the EUV range. In one such method, often termed laser produced plasma (“LPP”), the plasma can be produced by irradiating a fuel, such as a droplet, stream or cluster of material having the line-emitting element, with a laser beam. Source collector module SO may be part of an EUV radiation system including a laser (not shown in FIG. 14), for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation. In this example, the laser may not be considered to form part of the lithographic apparatus and the radiation beam can be passed from the laser to the source collector module with the aid of a beam delivery system comprising, for example, suitable directing mirrors and/or a beam expander. In other examples, the source may be an integral part of the source collector module, for example when the source is a discharge produced plasma EUV generator, often termed a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder, or capacitive sensor), the substrate table WT can be moved accurately (e.g. to position different target portions C in the path of radiation beam B). Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus LPA could be used in at least one of the following modes, step mode, scan mode, and stationary mode. In step mode, the support structure (e.g. patterning device table) MT and the substrate table WT are kept essentially stationary, while an entire pattern imparted to the radiation beam is projected onto a target portion C at one time (e.g., a single static exposure). The substrate table WT is then shifted in the X and/or Y direction so that a different target portion C can be exposed. In scan mode, the support structure (e.g. patterning device table) MT and the substrate table WT are scanned synchronously while a pattern imparted to the radiation beam is projected onto target portion C (i.e. a single dynamic exposure). The velocity and direction of substrate table WT relative to the support structure (e.g. patterning device table) MT may be determined by the (de)magnification and image reversal characteristics of the projection system PS. In stationary mode, the support structure (e.g. patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

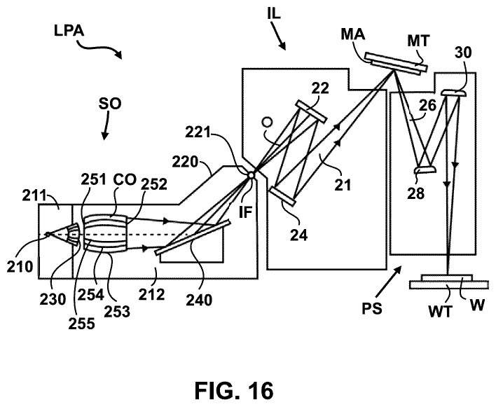

FIG. 16 is a detailed view of the lithographic projection apparatus shown in FIG. 15. As shown in FIG. 16, the LPA can include the source collector module SO, the illumination system IL, and the projection system PS. The source collector module SO is configured such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the hot plasma 210 is created to emit radiation in the EUV range of the electromagnetic spectrum. The hot plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap 230, which may be and/or include a barrier (described below) also includes a channel structure. The collector chamber 211 may include a radiation collector CO which may be a grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the line “O”. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently, the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT. More elements than shown may generally be present in illumination optics unit IL and projection system PS. The grating spectral filter 240 may optionally be present, depending upon the type of lithographic apparatus, for example. Further, there may be more mirrors present than those shown in the figures, for example there may be 1-6 additional reflective elements present in the projection system PS than shown in FIG. 16.

Collector optic CO, as illustrated in FIG. 16, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

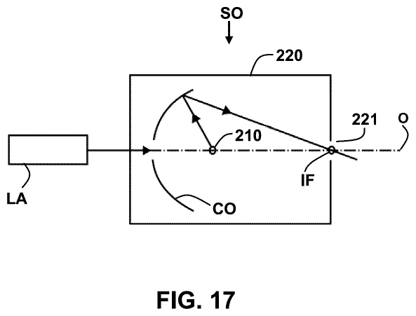

FIG. 17 is a detailed view of source collector module SO of the lithographic projection apparatus LPA (shown in previous figures). Source collector module SO may be part of an LPA radiation system. A laser LA can be arranged to deposit laser energy into a fuel, such as xenon (Xe), tin (Sn) or lithium (Li), creating the highly ionized plasma 210 with electron temperatures of several 10”s of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging system for imaging sub wavelength features, and may be especially useful with emerging imaging technologies capable of producing increasingly shorter wavelengths. Emerging technologies include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

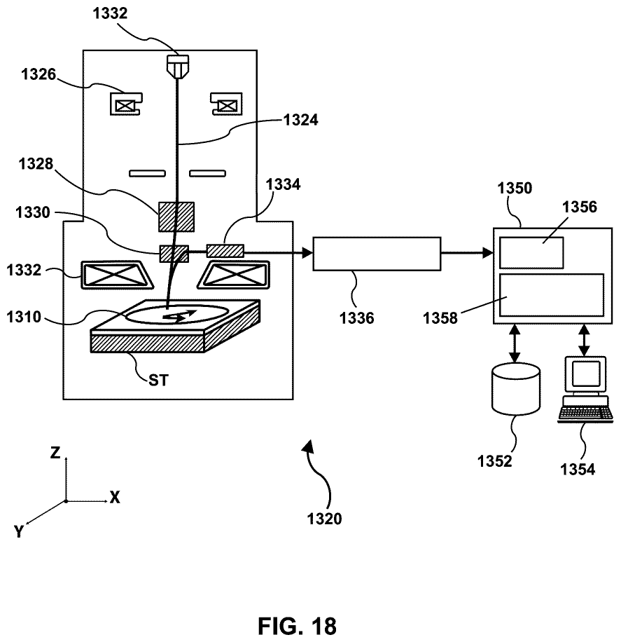

FIG. 18 schematically depicts an embodiment of an electron beam inspection apparatus 1320 (e.g., that may be used for and/or associated with one or more of the operations described herein). In some embodiments, the inspection apparatus may be an electron beam inspection apparatus (e.g., the same as or similar to a scanning electron microscope (SEM)) that yields an image of a structure (e.g., some or all the structure of a device, such as an integrated circuit) exposed or transferred on the substrate. A primary electron beam 1324 emitted from an electron source 1322 is converged by condenser lens 1326 and then passes through a beam deflector 1328, an E×B deflector 1330, and an objective lens 1332 to irradiate a substrate 1310 on a substrate table ST at a focus.

When the substrate 1310 is irradiated with electron beam 1324, secondary electrons are generated from the substrate 1310. The secondary electrons are deflected by the E×B deflector 1330 and detected by a secondary electron detector 1334. A two-dimensional electron beam image can be obtained by detecting the electrons generated from the sample in synchronization with, e.g., two-dimensional scanning of the electron beam by beam deflector 1328 or with repetitive scanning of electron beam 1324 by beam deflector 1328 in an X or Y direction, together with continuous movement of the substrate 1310 by the substrate table 1312 in the other of the X or Y direction. Thus, in an embodiment, the electron beam inspection apparatus has a field of view for the electron beam defined by the angular range into which the electron beam can be provided by the electron beam inspection apparatus (e.g., the angular range through which the deflector 1328 can provide the electron beam 1324). Thus, the spatial extent of the field of the view is the spatial extent to which the angular range of the electron beam can impinge on a surface (wherein the surface can be stationary or can move with respect to the field).

As shown in FIG. 18, a signal detected by secondary electron detector 1334 may be converted to a digital signal by an analog/digital (A/D) converter 1336, and the digital signal may be sent to an image processing system 1350. In an embodiment, the image processing system 1350 may have memory 1356 to store all or part of digital images for processing by a processing unit 1358. The processing unit 1358 (e.g., specially designed hardware or a combination of hardware and software or a computer readable medium comprising software) is configured to convert or process the digital images into datasets representative of the digital images. In an embodiment, the processing unit 1358 is configured or programmed to cause execution of an operation (e.g., SEM inspection) described herein. Further, image processing system 1350 may have a storage medium 1352 configured to store the digital images and corresponding datasets in a reference database. A display device 1354 may be connected with the image processing system 1350, so that an operator can conduct necessary operation of the equipment with the help of a graphical user interface.

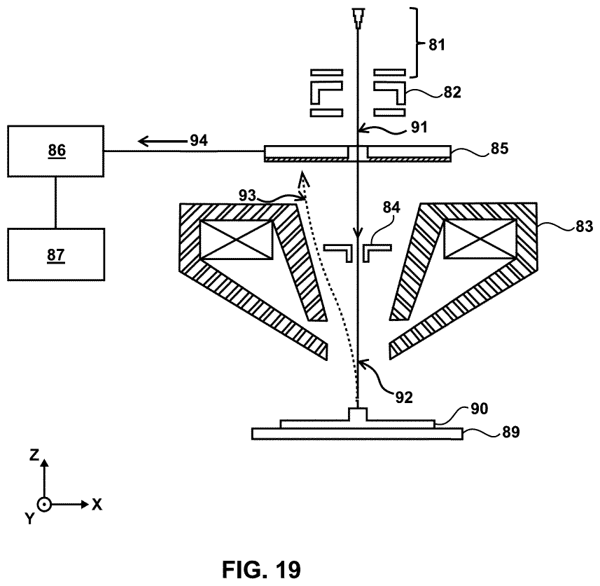

FIG. 19 schematically illustrates another embodiment of an inspection apparatus. The system is used to inspect a sample 90 (such as a substrate) on a sample stage 89 and comprises a charged particle beam generator 81, a condenser lens module 82, a probe forming objective lens module 83, a charged particle beam deflection module 84, a secondary charged particle detector module 85, an image forming module 86, and/or other components. The charged particle beam generator 81 generates a primary charged particle beam 91. The condenser lens module 82 condenses the generated primary charged particle beam 91. The probe forming objective lens module 83 focuses the condensed primary charged particle beam into a charged particle beam probe 92. The charged particle beam deflection module 84 scans the formed charged particle beam probe 92 across the surface of an area of interest on the sample 90 secured on the sample stage 89. In some embodiments, the charged particle beam generator 81, the condenser lens module 82, and the probe forming objective lens module 83, or their equivalent designs, alternatives or any combination thereof, together form a charged particle beam probe generator which generates the scanning charged particle beam probe 92.

The secondary charged particle detector module 85 detects secondary charged particles 93 emitted from the sample surface (maybe also along with other reflected or scattered charged particles from the sample surface) upon being bombarded by the charged particle beam probe 92 to generate a secondary charged particle detection signal 94. The image forming module 86 (e.g., a computing device) is coupled with the secondary charged particle detector module 85 to receive the secondary charged particle detection signal 94 from the secondary charged particle detector module 85 and accordingly form at least one scanned image. In an embodiment, the secondary charged particle detector module 85 and image forming module 86, or their equivalent designs, alternatives or any combination thereof, together form an image forming apparatus which forms a scanned image from detected secondary charged particles emitted from sample 90 being bombarded by the charged particle beam probe 92.

In an embodiment, a monitoring module 87 is coupled to the image forming module 86 of the image forming apparatus to monitor, control, etc. the patterning process and/or derive a parameter for patterning process design, control, monitoring, etc. using the scanned image of the sample 90 received from image forming module 86. In some embodiments, the monitoring module 87 is configured or programmed to cause execution of an operation described herein. In some embodiments, the monitoring module 87 comprises a computing device. In some embodiments, the monitoring module 87 comprises a computer program configured to provide functionality described herein. In some embodiments, a probe spot size of the electron beam in the system of FIG. 14 is significantly larger compared to, e.g., a CD, such that the probe spot is large enough so that the inspection speed can be fast. However, the resolution may be lower because of the large probe spot.

SEM images, from, e.g., the system of FIG. 13 and/or FIG. 14, may be processed to extract dimensions, shapes, contours, and/or other information that describe the edges of objects, representing semiconductor device structures, in the image. The shapes, contours, and/or other information may be quantified via metrics, such as CD, at user-defined cut-lines and/or in other locations. In some embodiments, the images of device structures are compared and quantified via metrics, such as an edge-to-edge distance (CD) measured on extracted contours or simple pixel differences between images. Alternatively, metrics can include EP gauges and/or other parameters.

Embodiments of the present disclosure can be further described by using the following clauses.

1. One or more non-transitory, computer readable media storing a machine learning prediction model and instructions that, when executed by one or more processors, cause the one or more processors to:

receive input information including geometry information and/or patterning process information for a semiconductor device manufacturing process;

predict, using the machine learning prediction model, output semiconductor device geometry based on the input information, the output semiconductor device geometry comprising a representation of pattern probability in a plurality of dimensions, the predicting comprising determining an edge placement error (EPE) metric associated with one or more features of a pattern based on the input information and/or the output semiconductor device geometry;

receive new input information determined based on an adjustment to the semiconductor device manufacturing process, the adjustment determined based on the output semiconductor device geometry; and

predict, using the machine learning model, updated output semiconductor device geometry (i) based on the new input information, (ii) including determining an updated EPE metric based on the new input information and/or the updated output semiconductor device geometry.

2. The media of clause 1, wherein the representation of pattern probability comprises a pattern probability image that comprises predicted two-dimensional substrate geometry for one or more features of the pattern.
3. The media of any of clauses 1-2, wherein the representation of pattern probability comprises predicted two-dimensional geometry of one or more vias in a semiconductor device.
4. The media of any of clauses 1-3, wherein the instructions are further configured to cause the one or more processors to predict, with the machine learning prediction model, one or both of (1) a symmetric or asymmetric stochastic edge placement error band and (2) a stochastic failure rate, based on a pattern probability image.
5. The media of any of clauses 1-4, wherein the input information comprises one or both of a simulated aerial image and a simulated resist image.
6. One or more non-transitory, computer readable media storing a machine learning prediction model and instructions that, when executed by one or more processors, cause the one or more processors to:

receive input information including geometry information and/or process information for a pattern; and

predict, using the machine learning prediction model, multi-dimensional output substrate geometry based on the input information, the predicting comprising determining an edge placement error (EPE) metric associated with one or more features of the pattern based on the input information and/or the output substrate geometry.

7. The media of clause 6, wherein the EPE metric is symmetric or asymmetric for the one or more features of the pattern.
8. The media of clause 7, wherein an asymmetric EPE metric has a non-Gaussian distribution.
9. The media of any of clauses 7-8, wherein the machine learning prediction model is trained using asymmetrically distributed training data such that weights and/or parameters of the trained machine learning prediction model facilitate determination of the symmetric or asymmetric EPE metric.
10. The media of clause 9, wherein the asymmetrically distributed training data comprises asymmetrically distributed EPE metrics determined from multi-dimensional probability images associated with asymmetrically distributed critical dimension (CD) values.
11. The media of any of clauses 6-10, wherein the multi-dimensional output substrate geometry indicates variability in shapes of features of the pattern.
12. The media of any of clauses 6-11, wherein the multi-dimensional output substrate geometry indicates a probability that given geometry occupies a given location on a substrate.
13. The media of any of clauses 6-12, wherein the multi-dimensional output substrate geometry comprises a representation of pattern probability in a plurality of dimensions.
14. The media of clause 13, wherein the representation of pattern probability comprises a pattern probability image that comprises predicted probabilities of two-dimensional substrate geometry for the one or more features of the pattern.
15. The media of clause 14, wherein the pattern probability image comprises a plurality of stacked images comprising predicted probabilities of two-dimensional substrate geometry for one or more vias.
16. The media of any of clauses 6-15, wherein the instructions are further configured to cause the one or more processors to predict, with the machine learning prediction model, one or both of (1) a symmetric or asymmetric stochastic edge placement error band and (2) a stochastic failure rate, based on the multi-dimensional output substrate geometry.
17. The media of any of clauses 6-16, wherein the instructions are further configured to cause the one or more processors to tune the machine learning prediction model such that the multi-dimensional output substrate geometry matches a measured stochastic edge placement error band or measured failure rate.
18. The media of any of clauses 6-17, wherein the instructions are further configured to cause the one or more processors to tune the machine learning prediction model such that the multi-dimensional output substrate geometry corresponds to, or matches, a mean contour prediction from an optical proximity correction model or a lithography manufacturability check model.
19. The media of any of clauses 6-18, wherein the multi-dimensional output substrate geometry is associated with a pattern in a substrate in a semiconductor device and a patterning process comprises a semiconductor device manufacturing process.
20. The media of any of clauses 6-19, wherein the multi-dimensional output substrate geometry comprises a pattern probability image, and wherein the pattern probability image comprises predicted two-dimensional geometry of one or more vias in a semiconductor device.
21. The media of any of clauses 6-20, wherein the multi-dimensional output substrate geometry comprises a pattern probability image, and wherein the instructions are further configured to cause the one or more processors to use the pattern probability image for a lithography manufacturability check and/or pattern fidelity metrology in a semiconductor device manufacturing process.
22. The media of any of clauses 6-21, wherein the input information comprises one or more of a simulated aerial image, a simulated resist image, target substrate dimensions, or data from a scanner associated with semiconductor device manufacturing, for a semiconductor device.
23. The media of any of clauses 6-22, wherein the input information comprises a plurality of aerial images, and individual aerial images of the plurality of aerial images correspond to different heights in resist layers associated with a patterning process.
24. The media of any of clauses 6-23, wherein the machine learning prediction model comprises a neural network.
25. The media of any of clauses 6-24, wherein the process information comprises one or more parameters for one or more manufacturing processes performed for a semiconductor device.
26. The media of any of clauses 6-25, wherein the instructions are further configured to cause the one or more processors to train the machine learning prediction model with training information comprising one or more of aerial images, target pattern geometry, or patterning process parameters, and corresponding physical substrate measurements and/or predictions from a different non-machine learning prediction model.
27. The media of clause 26, wherein the corresponding physical substrate measurements and/or predictions from a different non-machine learning prediction model comprise training pattern probability images.
28. The media of any of clauses 6-27, wherein the instructions are further configured to cause the one or more processors to determine an adjustment for a semiconductor device manufacturing apparatus based on the predicted multi-dimensional output substrate geometry.
29. The media of any of clauses 6-28, wherein the instructions are further configured to cause the one or more processors to calibrate the machine learning prediction model based on one or both of after development inspection dimensions and after etch inspection dimensions associated with a semiconductor device manufacturing process.
30. A method for predicting substrate geometry associated with a patterning process, the method comprising:

receiving input information including geometry information and/or process information for a pattern; and

predicting, using a machine learning prediction model, multi-dimensional output substrate geometry based on the input information, the predicting comprising determining an edge placement error (EPE) metric associated with one or more features of the pattern based on the input information and/or the output substrate geometry.

31. The method of clause 30, wherein the EPE metric is symmetric or asymmetric for the one or more features of the pattern.
32. The method of clause 31, wherein an asymmetric EPE metric has a non-Gaussian distribution.
33. The method of any of clauses 31-32, wherein the machine learning prediction model is trained using asymmetrically distributed training data such that weights and/or parameters of the trained machine learning prediction model facilitate prediction of the symmetric or asymmetric EPE metric.
34. The method of clause 33, wherein the asymmetrically distributed training data comprises asymmetrically distributed EPE metrics determined from multi-dimensional probability images associated with asymmetrically distributed critical dimension (CD) values.
35. The method of any of clauses 30-34, wherein the multi-dimensional output substrate geometry indicates variability in shapes of features of the pattern.
36. The method of any of clauses 30-35, wherein the multi-dimensional output substrate geometry indicates a probability that given geometry occupies a given location on a substrate.
37. The method of any of clauses 30-36, wherein the multi-dimensional output substrate geometry comprises a representation of pattern probability in a plurality of dimensions.
38. The method of clause 37, wherein the representation of pattern probability comprises a pattern probability image that comprises predicted probabilities of two-dimensional substrate geometry for the one or more features of the pattern.
39. The method of clause 38, wherein the pattern probability image comprises a plurality of stacked images comprising predicted probabilities of two-dimensional substrate geometry for one or more vias.
40. The method of any of clauses 30-39, further comprising predicting, with the machine learning prediction model, one or both of (1) a symmetric or asymmetric stochastic edge placement error band and (2) a stochastic failure rate, based on the multi-dimensional output substrate geometry.
41. The method of any of clauses 30-40, further comprising tuning the machine learning prediction model such that the multi-dimensional output substrate geometry matches a measured stochastic edge placement error band or measured failure rate.
42. The method of any of clauses 30-41, further comprising tuning the machine learning prediction model such that the multi-dimensional output substrate geometry corresponds to, or matches, a mean contour prediction from an optical proximity correction model or a lithography manufacturability check model.
43. The method of any of clauses 30-42, wherein the multi-dimensional output substrate geometry is associated with a pattern in a substrate in a semiconductor device and the patterning process comprises a semiconductor device manufacturing process.
44. The method of any of clauses 30-43, wherein the multi-dimensional output substrate geometry comprises a pattern probability image, and wherein the pattern probability image comprises predicted two-dimensional geometry of one or more vias in a semiconductor device.
45. The method of any of clauses 30-44, wherein the multi-dimensional output substrate geometry comprises a pattern probability image, and wherein the method further comprises using the pattern probability image for a lithography manufacturability check and/or pattern fidelity metrology in a semiconductor device manufacturing process.
46. The method of any of clauses 30-45, wherein the input information comprises one or more of a simulated aerial image, a simulated resist image, target substrate dimensions, or data from a scanner associated with semiconductor device manufacturing, for a semiconductor device.
47. The method of any of clauses 30-46, wherein the input information comprises a plurality of aerial images, and individual aerial images of the plurality of aerial images correspond to different heights in resist layers associated with the patterning process.
48. The method of any of clauses 30-47, wherein the machine learning prediction model comprises a neural network.
49. The method of any of clauses 30-48, wherein the process information comprises one or more parameters for one or more manufacturing processes performed for a semiconductor device.
50. The method of any of clauses 30-49, further comprising training the machine learning prediction model with training information comprising one or more of aerial images, target pattern geometry, or patterning process parameters, and corresponding physical substrate measurements and/or predictions from a different non-machine learning prediction model.
51. The method of clause 50, wherein the corresponding physical substrate measurements and/or predictions from a different non-machine learning prediction model comprising training pattern probability images.
52. The method of any of clauses 30-51, further comprising determining an adjustment for a semiconductor device manufacturing apparatus based on the predicted multi-dimensional output substrate geometry.
53. The method of any of clauses 30-52, further comprising calibrating the machine learning prediction model based on one or both of after development inspection dimensions and after etch inspection dimensions associated with a semiconductor device manufacturing process.
54. A method comprising:
receiving, with one or more processors, input information including geometry information and/or patterning process information for a pattern on a substrate;
determining, with the one or more processors, an edge placement error (EPE) metric associated with one or more features of the pattern based on the input information; and
determining, with the one or more processors, one or more areas of the pattern on the substrate that have one or more potential defects based on the EPE metric.
   55. The method of clause 54, wherein the EPE metric is symmetric or asymmetric for the one or more features of the pattern.
   56. The method of clause 55, wherein an asymmetric EPE metric has a non-Gaussian distribution.
   57. The method of any of clauses 54-56, wherein the EPE metric is determined with a machine learning prediction model, and the machine learning prediction model is trained using asymmetrically distributed training data such that weights and/or parameters of the trained machine learning prediction model facilitate prediction of the EPE metric whether the EPE metric is symmetric or asymmetric.
   58. The method of clause 57, wherein the asymmetrically distributed training data comprises asymmetrically distributed EPE metrics determined from multi-dimensional probability images associated with asymmetrically distributed critical dimension (CD) values.
   59. The method of any of clauses 54-58, wherein the one or more areas of the pattern on the substrate that have the one or more potential defects comprise hot spots.
   60. The method of any of clauses 54-59, wherein the EPE metric is correlated to a yield associated with the pattern on the substrate.
   61. The method of any of clauses 54-60, wherein the input information comprises one or more parameters related to global overlay, a global critical dimension, local overlay, a local critical dimension, a line edge roughness, a local placement error, or a local critical dimension uniformity; and/or a value indicative of an interaction between two or more of the parameters.
   62. The method of any of clauses 54-61, wherein the input information is measured and/or simulated.
   63. A manufacturing process, the process comprising:
receiving, with one or more processors, input information including geometry information and/or patterning process information for a pattern on a substrate;
determining, with the one or more processors, an edge placement error (EPE) metric associated with one or more features of the pattern based on the input information; and
determining, with the one or more processors, one or more areas of the pattern on the substrate that have one or more potential defects based on the EPE metric.
   64. The process of clause 63, wherein the EPE metric is symmetric or asymmetric across the one or more features of the pattern.
   65. The process of clause 64, wherein an asymmetric EPE metric has a non-Gaussian distribution.
   66. The process of any of clauses 63-65, wherein the EPE metric is determined with a machine learning prediction model, and the machine learning prediction model is trained using asymmetrically distributed training data such that weights and/or parameters of the trained machine learning prediction model facilitate prediction of the EPE metric whether the EPE metric is symmetric or asymmetric.
   67. The process of clause 66, wherein the asymmetrically distributed training data comprises asymmetrically distributed EPE metrics determined from multi-dimensional probability images associated with asymmetrically distributed critical dimension (CD) values.
   68. The process of any of clauses 63-67, wherein the one or more areas of the pattern on the substrate that have the one or more potential defects comprise hot spots.
   69. The process of any of clauses 63-68, wherein the EPE metric is correlated to a yield associated with the pattern on the substrate.
   70. The process of any of clauses 63-69, wherein the input information comprises one or more parameters including global overlay, a global critical dimension, a local critical dimension, a feature edge roughness, a local critical dimension uniformity, mask critical dimension, mask placement error, scanner to scanner critical dimension, scanner to scanner overlay mismatches, patterning tool critical dimension, patterning tool overlay mismatches, or local and global variations of feature asymmetry; and/or a value indicative of an interaction/cross-talk between two or more of the parameters.
   71. The process of clause 70, wherein the EPE metric comprises a combination of two or more of the parameters and/or the value indicative of the interaction between two or more of the parameters.
   72. The process of clause 71, wherein the EPE metric is mathematically calculated and/or predicted based on one or more of the parameters and/or the value indicative of the interaction between two or more of the parameters.
   73. The process of any of clauses 63-72, wherein the input information is measured and/or simulated.
   74. The process of any of clauses 63-73, wherein the EPE metric is determined based on a target EPE probability level, the one or more processors configured such that the target EPE probability level is entered or selected by a user via a user interface.
   75. The process of any of clauses 63-74, wherein receiving the input information, determining the EPE metric, and determining the one or more areas of the pattern on the substrate that have one or more potential defects are performed as part of an assessment, improvement, prediction, or verification of semiconductor device performance, and wherein the assessment, improvement, prediction, or verification of semiconductor device performance comprises source mask optimization, optical proximity correction, a lithography manufacturability check, and/or a design for manufacturing flow associated with a semiconductor device.
   76. The process of any of clauses 63-75, wherein determining one or more areas of the pattern on the substrate that have one or more potential defects based on the EPE metric comprises determining a probability that a given feature of the pattern occupies a given location on the substrate.
   77. The process of any of clauses 63-76, wherein determining one or more areas of the pattern on the substrate that have one or more potential defects based on the EPE metric is based on a cost function that balances an acceptable defect probability with resources required to inspect a number of the one or more areas, wherein the acceptable defect probability is related to a number of the one or more areas of the pattern on the substrate that have the one or more potential defects that are targeted for inspection.
   78. The process of any of clauses 63-77, wherein determining the one or more areas of the pattern on the substrate that have the one or more potential defects based on the EPE metric comprises determining a pattern probability image for one or more features of the pattern.
   79. The process of clause 78, wherein the pattern probability image comprises predicted two-dimensional substrate geometry for one or more of the features.
   80. The process of any of clauses 63-79, wherein the input information comprises and/or is determined based on one or more of a predicted aerial image, target substrate dimensions, or data from a scanner and/or patterning process associated with semiconductor device manufacturing, for one or more layers of a semiconductor device.
   81. The process of any of clauses 63-80, further comprising determining an adjustment for a semiconductor device manufacturing apparatus based on the one or more areas of the pattern on the substrate that have the one or more potential defects.
   82. The process of clause 81, wherein the adjustment comprises one or more of a change in the pattern, a change in a mask, a change of a dose, a change in a focus, a change in an exposure, a change in a pupil, a change in an etch and/or deposition process temperature, or a change in an etch and/or deposition process time.
   83. The process of any of clauses 63-82, wherein the one or more processors comprise a computational lithography model, and wherein determining the EPE metric comprises predicting the EPE metric using the input information as input to the computational lithography model.
   84. The process of any of clauses 63-83, wherein the geometry information comprises one or more indications of a size and/or a position of one or more features of the pattern.
   85. A non-transitory computer readable medium having instructions thereon, the instructions when executed by a computer implementing the process of any of clauses 63-84.
   86. A non-transitory computer readable medium having instructions thereon, the instructions when executed by a computer causing the computer to:

receive input information including geometry information and/or patterning process information for a pattern on a substrate;

determine an edge placement error (EPE) metric associated with one or more features of the pattern based on the input information; and

identify one or more areas of the pattern on the substrate that have one or more potential defects based on the EPE metric.

87. The medium of clause 86, wherein the EPE metric is symmetric or asymmetric across the one or more features of the pattern.
88. The medium of clause 87, wherein an asymmetric EPE metric has a non-Gaussian distribution.
89. The medium of any of clauses 86-88, wherein the EPE metric is determined with a machine learning prediction model, and wherein the machine learning prediction model is trained using asymmetrically distributed training data such that weights and/or parameters of the trained machine learning prediction model facilitate prediction of the EPE metric whether the EPE metric is symmetric or asymmetric.
90. The medium of clause 89, wherein the asymmetrically distributed training data comprises asymmetrically distributed EPE metrics determined from multi-dimensional probability images associated with asymmetrically distributed critical dimension (CD) values.
91. The medium of any of clauses 86-90, wherein the one or more areas of the pattern on the substrate that have the one or more potential defects comprise hot spots.
92. The medium of any of clauses 86-91, wherein the EPE metric is correlated to a yield associated with the pattern on the substrate.
93. The medium of any of clauses 86-92, wherein the input information comprises one or more parameters including global overlay, a global critical dimension, a local critical dimension, a feature edge roughness, a local critical dimension uniformity, mask critical dimension, mask placement error, scanner to scanner critical dimension, scanner to scanner overlay mismatches, patterning tool critical dimension, patterning tool overlay mismatches, or local and global variations of feature asymmetry; and/or a value indicative of an interaction/cross-talk between two or more of the parameters.
94. The medium of clause 93, wherein the EPE metric comprises a combination of two or more of the parameters and/or the value indicative of the interaction between two or more of the parameters.
95. The medium of any of clauses 86-94, wherein the input information is measured and/or simulated.
96. The medium of any of clauses 86-95, wherein the EPE metric is determined based on a target EPE probability level, wherein the target EPE probability level is entered or selected by a user via a user interface.
97. The medium of any of clauses 86-96, wherein receiving the input information, determining the EPE metric, and determining the one or more areas of the pattern on the substrate that have one or more potential defects are performed as part of source mask optimization, optical proximity correction, a lithography manufacturability check, and/or a design for manufacturing flow associated with a semiconductor device.
98. The medium of any of clauses 86-97, wherein determining one or more areas of the pattern on the substrate that have one or more potential defects based on the EPE metric comprises determining a probability that a given feature occupies a given location on the substrate.
99. The medium of any of clauses 86-98, wherein determining one or more areas of the pattern on the substrate that have one or more potential defects based on the EPE metric is based on a cost function that balances a number of the one or more areas of the pattern on the substrate that have one or more potential defects versus resources required to inspect the number of the one or more areas.
100. The medium of any of clauses 86-99, wherein determining the one or more areas of the pattern on the substrate that have the one or more potential defects based on the EPE metric comprises determining a pattern probability image for one or more features of the pattern.

While the concepts disclosed herein may be used for wafer manufacturing on a substrate such as a silicon wafer, it shall be understood that the disclosed concepts may be used with any type of manufacturing system (e.g., those used for manufacturing on substrates other than silicon wafers). In addition, the combination and sub-combinations of disclosed elements may comprise separate embodiments. For example, separate embodiments of the machine learning prediction model may predict one or both of the stochastic edge placement error band and the stochastic failure rate based on the multi-dimensional output substrate geometry

The descriptions above are intended to be illustrative, not limiting. Thus, it will be apparent to one skilled in the art that modifications may be made as described without departing from the scope of the claims set out below.

1. One or more non-transitory, computer-readable media storing a machine learning prediction model and instructions that, when executed by one or more processors, are configured to cause the one or more processors to at least:
receive input information including geometry information and/or process information for a pattern; and
predict, using the machine learning prediction model, multi-dimensional output substrate geometry based on the input information, the prediction comprising determination of an edge placement error (EPE) metric associated with one or more features of the pattern based on the input information and/or the output substrate geometry.

2. The media of claim 1, wherein the EPE metric is symmetric or asymmetric for the one or more features of the pattern.

3. The media of claim 2, wherein the machine learning prediction model is trained using asymmetrically distributed training data such that weights and/or parameters of the trained machine learning prediction model facilitate determination of the symmetric or asymmetric EPE metric.

4. The media of claim 3, wherein the asymmetrically distributed training data comprises asymmetrically distributed EPE metrics determined from multi-dimensional probability images associated with asymmetrically distributed critical dimension (CD) values.

5. The media of claim 1, wherein the multi-dimensional output substrate geometry indicates variability in shapes of features of the pattern.

6. The media of claim 1, wherein the multi-dimensional output substrate geometry indicates a probability that a given geometry occupies a given location on a substrate.

7. The media of claim 1, wherein the multi-dimensional output substrate geometry comprises a representation of pattern probability in a plurality of dimensions.

8. The media of claim 1, wherein the instructions are further configured to cause the one or more processors to predict, with the machine learning prediction model, (1) a symmetric or asymmetric stochastic edge placement error band and/or (2) a stochastic failure rate, based on the multi-dimensional output substrate geometry.

9. The media of claim 1, wherein the instructions are further configured to cause the one or more processors to tune the machine learning prediction model such that the multi-dimensional output substrate geometry matches a measured stochastic edge placement error band or measured failure rate, or matches a mean contour prediction from an optical proximity correction model or a lithography manufacturability check model.

10. The media of claim 1, wherein the multi-dimensional output substrate geometry comprises a pattern probability image, and wherein the instructions are further configured to cause the one or more processors to use the pattern probability image for a lithography manufacturability check and/or pattern fidelity metrology in a semiconductor device manufacturing process.

11. The media of claim 1, wherein the input information comprises one or more selected from: a simulated aerial image, a simulated resist image, target substrate dimensions, or data from a lithography apparatus associated with semiconductor device manufacturing, for a semiconductor device.

12. The media of claim 1, wherein the input information comprises a plurality of aerial images, and individual aerial images of the plurality of aerial images correspond to different heights in resist layers associated with a patterning process.

13. The media of claim 1, wherein the instructions are further configured to cause the one or more processors to train the machine learning prediction model with training information comprising one or more selected from: aerial images, target pattern geometry, or patterning process parameters, and corresponding physical substrate measurements and/or predictions from a different non-machine learning prediction model.

14. The media of claim 1, wherein the instructions are further configured to cause the one or more processors to determine an adjustment for a semiconductor device manufacturing apparatus based on the predicted multi-dimensional output substrate geometry.

15. The media of claim 1, wherein the instructions are further configured to cause the one or more processors to calibrate the machine learning prediction model based on one or both of after development inspection dimensions and after etch inspection dimensions associated with a semiconductor device manufacturing process.

16. One or more non-transitory, computer-readable media storing a machine learning prediction model and instructions that, when executed by one or more processors, are configured to cause the one or more processors to at least:
receive input information including geometry information and/or patterning process information for a device manufacturing process; and
predict, using the machine learning prediction model, output device geometry based on the input information, the output device geometry comprising a representation of pattern probability in a plurality of dimensions, the prediction comprising determination of an edge placement error (EPE) metric associated with one or more features of a pattern based on the input information and/or the output device geometry.

17. The media of claim 16, wherein the instructions are further configured to cause the one or more processors to:
receive new input information determined based on an adjustment to the device manufacturing process, the adjustment determined based on the output device geometry; and
predict, using the machine learning model, updated output device geometry based on the new input information, including determination of an updated EPE metric based on the new input information and/or the updated output device geometry.

18. The media of claim 16, wherein the representation of pattern probability comprises a pattern probability image that comprises predicted two-dimensional substrate geometry for one or more features of the pattern.

19. The media of claim 16, wherein the representation of pattern probability comprises predicted two-dimensional geometry of one or more vias in a semiconductor device.

20. The media of claim 16, wherein the instructions are further configured to cause the one or more processors to predict, with the machine learning prediction model, (1) a symmetric or asymmetric stochastic edge placement error band and/or (2) a stochastic failure rate, based on a pattern probability image.
